(19) United States
(12) Patent Application Publication
(10) Pub. No.: US 2009/0283739 A1
(43) Pub. Date: Nov. 19, 2009

(54) NONVOLATILE STORAGE DEVICE AND METHOD FOR MANUFACTURING SAME

(76) Inventor: Masahiro Kiyotoshi, Mie-Ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/408,598

(22) Filed: Mar. 20, 2009

(30) Foreign Application Priority Data
May 19, 2008 (JP) 2008-130977
May 19, 2008 (JP) 2008-131353

(51) Int. Cl. H01L 29/786; H01L 21/28

(52) U.S. Cl. 257/4; 438/584; 257/E21.209; 257/E29.296

(57) ABSTRACT

There is provided a nonvolatile storage device including a plurality of component memory layers. The plurality of component memory layers are stacked In a direction perpendicular to a layer surface. Each of the plurality of component memory layers includes a first wiring, a second wiring provided non-parallel to the first wiring and a stacked structure unit provided between the first wiring and the second wiring and including a recording layer. At least one of the first wiring and the second wiring includes a protruding portion provided on a portion opposed to the recording layer and protruding toward the recording layer side.

### CROSS-REFERENCE TO RELATED APPLICATIONS

This application is based upon and claims the benefit of priority from the prior Japanese Patent Application No. 2008-130977, filed on May 19, 2008 and the prior Japanese Patent Application No. 2008-131353, filed on May 19, 2008; the entire contents of which are incorporated herein by reference.

### BACKGROUND OF THE INVENTION

1. Field of the Invention

This invention relates to a nonvolatile storage device and a method for manufacturing the same.

2. Background Art

Nonvolatile memory typified by NAND flash memory is used widely for large-capacity data storage in mobile telephones, digital still cameras, USB memory, silicon audio, and the like. The market continues to grow due to the reduction of manufacturing costs per bit enabled by rapid downsizing. However, NAND flash memory utilizes a transistor operation that records information using a transistor threshold voltage shift. It is considered that improvements in reliability, higher-speed operations, higher bit densities, and suppression of the fluctuation of program/erase characteristics will reach a limit. The development of a new nonvolatile memory is desirable.

On the other hand, for example, phase change memory or resistance change memory operates by utilizing a variable resistance state of a resistive material. Therefore, a transistor operation is unnecessary during programming/erasing, and the program/erase characteristics improve as the size of the resistive material is reduced. Hence, this technology is expected to respond to future needs by realizing highly uniform characteristics, high reliability, higher-speed operations, and higher bit density.

Meanwhile, nonvolatile memory elements are often used in mobile devices, therefore reduction of their operating current becomes strongly required as their bit density increases.

Nonvolatile memory elements that utilize a variable resistance material tend to require a relatively large operating current. Reducing the operating current may affect the variable resistance state of the resistive material. Therefore, efforts to reduce operating current using conventional art are limited.

Technology is discussed regarding a self-aligning nonvolatile storage device memory structure that requires two array relation masks to specify bit lines and word lines based on a phase change material including a chalcogenide (for example, refer to JP-A 2003-303941 (Kokai)).

In such a memory, information recorded in the recording layer is read by a current flowing through the recording layer. For this purpose, a rectifying element such as a diode is provided to regulate the direction of the current in order to prevent stray current (current that flows in the reverse direction; sneak current) in each memory cell during programming/reading.

### SUMMARY OF THE INVENTION

According to an aspect of the invention, there is provided a nonvolatile storage device including a plurality of component memory layers, the plurality of component memory layers being stacked in a direction perpendicular to a layer surface, each of the plurality of component memory layers including: a first wiring; a second wiring provided non-parallel to the first wiring; and a stacked structure unit provided between the first wiring and the second wiring, the stacked structure unit including a recording layer having a resistance changing due to at least one of an electric field applied and a current provided by the first wiring and the second wiring, at least one of the first wiring and the second wiring having a protruding portion provided on a portion opposed to the recording layer and protruding toward the recording layer side,

According to another aspect of the invention, there is provided a method for manufacturing a nonvolatile storage device, the nonvolatile storage device including component memory layers multiply stacked on one another, the component memory layer including a first wiring aligned in a first direction, a second wiring aligned in a second direction non-parallel to the first direction, and a stacked structure unit provided between the first wiring and the second wiring, the stacked structure unit including a recording layer and a rectifying element layer, the method including: a first step stacking, on a substrate, a stacked film serving as the stacked structure unit and at least one of a first conductive film serving as the first wiring and a second conductive film serving as the second wiring in a stacking direction perpendicular to the first direction and the second direction, and processing the stacked film and one of the first conductive film and the second conductive film into a band configuration aligned in the first direction; a second step filling an inter-layer dielectric film between the stacked film and at least one of the first conductive film and the second conductive film processed into the band configuration; and a third step sequentially patterning the stacked film, the inter-layer dielectric film, and another of the first conductive film and the second conductive film into a band configuration aligned in the second direction, at least one of the first step, the second step and the third step performing at least forming a protruding portion being formed on at least one of the first wiring and the second wiring, and a portion of the stacked film, the protruding portion protruding in the stacking direction, and forming at least a portion of the stacked film aligned in one of the first direction and the second direction.

### BRIEF DESCRIPTION OF THE DRAWINGS

FIG. 1 is a schematic perspective view illustrating the structure of a relevant part of a nonvolatile storage device according to a first embodiment of the invention;

FIGS. 2A and 2B are a circuit diagram and a schematic perspective view, respectively, illustrating the configuration of the nonvolatile storage device according to the first embodiment of the invention;

FIG. 3 is a schematic perspective view illustrating the structure of a relevant part of a nonvolatile storage device of a first comparative example;

FIGS. 4A and 4B are schematic perspective views illustrating structures of relevant parts of other nonvolatile storage devices according to the first embodiment of the invention;

FIGS. 5A to 5C are schematic cross-sectional views in order of the steps, illustrating a method for manufacturing the nonvolatile storage device according to a first example of the invention;

FIGS. 6A and 6B are drawings continuing from FIG. 5C;

FIGS. 7A and 7B are drawings continuing from FIG. 6B;

FIGS. 8A and 8B are drawings continuing from FIG. 7B;

FIG. 9 is a drawing continuing from FIG. 8B;

FIGS. 10A to 10C are schematic cross-sectional views in order of the steps, illustrating a method for manufacturing a nonvolatile storage device according to a second example of the invention;

FIGS. 11A and 11B are drawings continuing from FIG. 10C;

FIG. 12 is a drawing continuing from FIG. 11B;

FIG. 13 is a drawing continuing from FIG. 12;

FIG. 14 is a flowchart illustrating the method for manufacturing the nonvolatile storage device according to the second embodiment of the invention;

FIG. 15 is a flowchart illustrating a method for manufacturing a nonvolatile storage device according to a third embodiment of the invention;

FIG. 16 is a flowchart illustrating a method for manufacturing a nonvolatile storage device according to a fourth embodiment of the invention;

FIGS. 17A and 17B are schematic cross-sectional views illustrating the configuration of a nonvolatile storage device according to a fifth embodiment of the t invention;

FIG. 18 is a schematic perspective view illustrating the configuration of another nonvolatile storage device according to the fifth embodiment of the invention;

FIG. 19 is another schematic cross-sectional view illustrating the configuration of the nonvolatile storage device according to the fifth embodiment of the invention;

FIGS. 20A and 20B are schematic cross-sectional views illustrating the configuration of a nonvolatile storage device according to a third comparative example;

FIGS. 21A and 21B are schematic cross-sectional views illustrating configurations of a nonvolatile storage device according to a fifth embodiment of the invention and the nonvolatile storage device of the third comparative example, respectively;

FIGS. 22A and 22B are schematic cross-sectional views illustrating operations of the nonvolatile storage device according to the fifth embodiment of the invention and the nonvolatile storage device of the third comparative example, respectively;

FIGS. 23A and 23B are schematic cross-sectional views illustrating the configuration of another nonvolatile storage device according to the fifth embodiment of the invention;

FIGS. 24A and 24B are schematic cross-sectional views illustrating the operation of the nonvolatile storage device according to the fifth embodiment of the invention;

FIGS. 25A and 25B are schematic cross-sectional views illustrating configurations of other nonvolatile storage devices according to the fifth embodiment of the invention;

FIGS. 26A and 26B are schematic cross-sectional views illustrating the configuration of another nonvolatile storage device according to the fifth embodiment of the invention;

FIG. 27 is a schematic cross-sectional view illustrating the operation of the nonvolatile storage device according to the fifth embodiment of the invention;

FIGS. 28A to 28C are schematic perspective views in order of the steps, illustrating a method for manufacturing a nonvolatile storage device according to a third example;

FIGS. 29A and 29B are drawings continuing from FIG. 28C;

FIG. 30 is a schematic perspective view illustrating the configuration of a nonvolatile storage device of a fourth comparative example;

FIG. 31 is a schematic perspective view illustrating the configuration of a nonvolatile storage device of a fourth example according to the fifth embodiment of the invention;

FIGS. 32A and 32B are schematic perspective views in order of the steps, illustrating a method for manufacturing the nonvolatile storage device according to the fourth example of the invention;

FIGS. 33A and 33B are drawings continuing from FIG. 32B;

FIGS. 34A and 34B are drawings continuing from FIG. 33B;

FIGS. 35A to 35C are schematic cross-sectional views in order of the steps, illustrating a method for manufacturing a nonvolatile storage device according to a fifth example of the invention; and

FIGS. 36A and 36B are drawings continuing from FIG. 35C.

### DETAILED DESCRIPTION OF THE INVENTION

Hereinbelow, embodiments of the invention are described in detail with reference to the drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

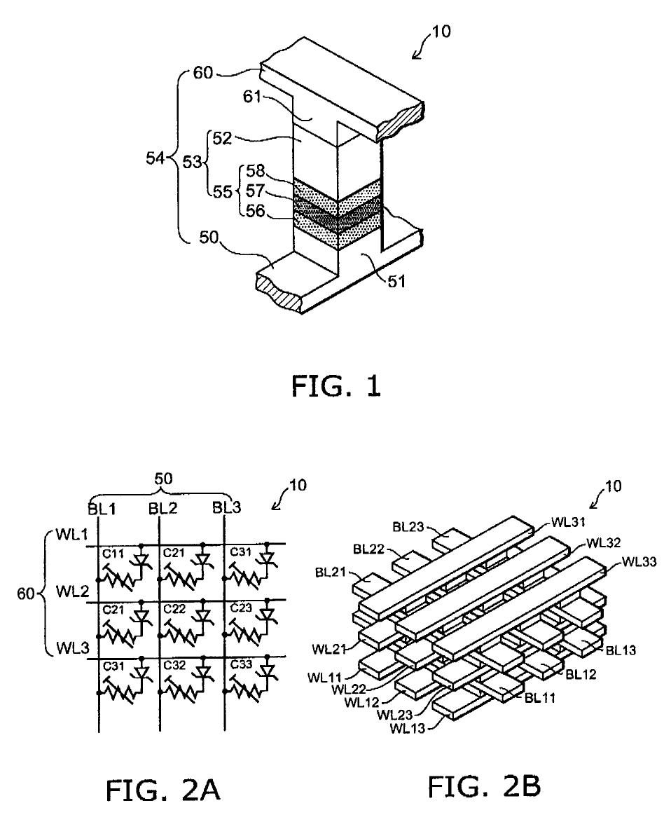

FIG. 1 is a schematic perspective view illustrating a structure of a relevant part of a nonvolatile storage device according to a first embodiment of the invention.

FIGS. 2A and 2B are a circuit diagram and a schematic perspective view, respectively, illustrating the structure of the nonvolatile storage device according to the first embodiment of the invention.

As illustrated in FIG. 1, the nonvolatile storage device 10 according to the first embodiment of the invention includes a structure of component memory layers 54 multiply stacked on one another; the component memory layer 54 including: a first wiring 50 (for example, a word line); a second wiring 60 (for example, a bit line) provided non-parallel to, that is, to intersect three dimensionally with, the first wiring; and a stacked structure unit 53 that includes a recording layer (resistance change layer or phase change layer) 57 provided between the first wiring and the second wiring. At least one of the first wiring 50 and the second wiring 60 have protruding portions 51 and 61 provided on a portion opposite to the recording layer 57 (stacked structure unit 53). The protruding portions 51 and 61 protrude toward the recording layer 57 (stacked structure unit 53) side.

The recording layer 57 is, for example, a layer that can reversibly transit from a first state to a second state having a different resistance than that of the first state due to a current supplied via the first wiring 50 and the second wiring 60. In other words, a resistance of the recording layer 57 changes due to at least one of an electric field applied and a current provided by the first wiring 50 and the second wiring 60.

The stacked structure unit 53 of the nonvolatile storage device 10 illustrated in FIG. 1 includes a stacked recording layer unit 55 and a rectifying element (for example, a diode) 52. The stacked recording layer unit 55 includes a first barrier metal 56 and a second barrier metal 58; and the variable resistor layer 57 is provided between the first barrier metal 56 and the second barrier metal 58. The rectifying element 52 may include a barrier metal, which is not illustrated. That is, the stacked structure unit 53 includes at least one of a barrier metal provided on the first wiring 50 side of the stacked structure unit 53 and a barrier metal provided on the second wiring 60 side of the stacked structure unit 53.

In the description above, the first wiring 50 is assumed to be a word line, and the second wiring 60 is assumed to be a bit line; but the first wiring 50 can be assumed to be a bit line, and the second wiring 60 can be assumed to be a word line. In other words, the bit lines and the word lines described herein in the nonvolatile storage device and the method for manufacturing the same according to embodiments are mutually interchangeable. Further, as described below, the component memory layers 54 multiply stacked on one another may, for example, enable the second wiring 60 of the lower layer component memory layer 54 and the first wiring 50 of the upper layer component memory layer 54 to be shared. In other words, the second wiring 60 of a lower layer can be the first wiring 50 wiring 60 of an upper layer. The description below assumes that the first wiring 50 is a word line and the second wiring 60 is a bit line.

As illustrated in FIG. 2A, the nonvolatile storage device 10 according to this embodiment includes a plurality of unit cells C11, C12, C13, C21, C22, C23, C31, C32, and C33 arranged in a matrix configuration. Each unit cell C11, C12, C13, C21, C22, C23, C31, C32, and C33 is defined by a plurality of bit lines BL1, BL2, and BL3, and by a plurality of word lines WL1, WL2, and WL3. The stacked structure unit 53 including the recording layer 57 is provided at each crosspoint where a word line and a bit line intersect. To avoid complexity in the drawings, three word lines and three bit lines are illustrated; but the invention is not limited thereto. The number of bit lines and word lines is arbitrary.

The stacked structure unit 53 provided between the first wiring 50 and the second wiring 60 illustrated in FIG. 1 is one of the unit cells described above.

In the nonvolatile storage device 10 according to this embodiment illustrated in FIG. 2B, component memory layers 54, which include stacked structure units 53 disposed between word lines and bit lines, are then stacked. In the example of FIG. 2B, four component memory layers 54 are stacked on one another. However, the invention is not limited thereto; and the number of component memory layers 54 to be stacked on one another is arbitrary.

The nonvolatile storage device 10 illustrated in FIG. 2B includes a shared bit line/word line structure in which word lines and bit lines are shared by cells (component memory layers 54) above and below. In other words, one of a first wiring 50 and a second wiring 60 of one of a plurality of component memory layers is shared as one of a first wiring 50 and a second wiring 60 of another component memory layer adjacent to the one of the plurality of component memory layers in a direction perpendicular to the layer surface.

However, the invention is not limited thereto; and each of the stacked component memory layers 54 may include a word line (for example, the first wiring 50) and a bit line (for example, the second wiring 60) that are each provided independently.

Thus, the nonvolatile storage device 10 includes a structure in which the stacked structure unit 53 including the recording layer 57 is disposed between wirings (bit lines and word lines) above and below.

Although the stacked memory layer unit 55 is disposed on the word line 50 side and the rectifying element 52 is disposed on the bit line 60 side in FIG. 1, the invention is not limited thereto. The disposition order (stack order) of the stacked memory layer unit 55 and the rectifying element 52 is arbitrary.

In the nonvolatile storage device 10 according to this embodiment illustrated in FIG. 1, the stacked structure unit 53 including the recording layer 57 is disposed between the protruding portions 51 and 61. Hereinafter in the specification of the application, “T-shaped portion 51” refers to the protruding portion 51 on the word line 50 side, that is, the T-shaped portion 51 that is drawn out from the word line 50. Similarly, “T-shaped portion 61” refers to the protruding portion 61 on the bit line 60 side, that is, the T-shaped portion 61 drawn out from the bit line 60.

In other words, the stacked structure unit 53 including the recording layer 57 is disposed between the T-shaped portions 51 and 61 drawn out from the word line 50 and the bit line 60.

As illustrated in FIG. 1, the stacked memory layer unit 55 includes the first barrier metal 56 on the word line 50 side, the recording layer 57, and the second barrier metal 58 on the bit line 60 side. Here, the resistivities of the protruding portions (T-shaped portions) 51 and 52 are lower than that of the first barrier metal 56 and lower than that of the second barrier metal 58. The first and second barrier metals 56 and 58 described above may be provided as necessary. For example, in the case where the recording layer 57 includes a phase change element, at least one of the first and second barrier metals 56 and 58 may also be used as a heater.

Additionally, the rectifying element 52 may include a barrier metal. In such a case, the resistivities of the protruding portions 51 and 61 also may be set lower than that of the barrier metal of the rectifying element.

That is, the stacked structure unit 53 of the nonvolatile storage device 10 according to this embodiment may include at least one of a barrier metal provided on the first wiring 50 side of the stacked structure unit 53 and a barrier metal provided on the second wiring 60 side of the stacked structure unit 53; and the resistivities of the protruding portions 51 and 61 can be set lower than the resistivity of the at least one of the barrier metals.

Thus, in the nonvolatile storage device 10 according to this embodiment, the stacked structure unit 53 including the recording layer 57 is disposed between the T-shaped portions 51 and 61 provided on the word line 50 and the bit line 60. The distance between these wirings and the variable resistor layer 57 is thereby increased.

After switching a resistance change memory to a high resistance state by programming, erasing is performed by, for example, joule heat when erasing back to a low resistance state.

By providing the recording layer 57 between the T-shaped portions 51 and 61 of the word line 50 and the bit line 60 of the nonvolatile storage device 10 according to this embodiment, the distance between the recording layer 57 and the wirings can be increased; wirings can be prevented from acting as heat sinks; and, for example, the erasing current can be reduced.

Thus, the nonvolatile storage device 10 according to this embodiment enables fast programming/erasing speeds and a low programming/erasing current.

### FIRST COMPARATIVE EXAMPLE

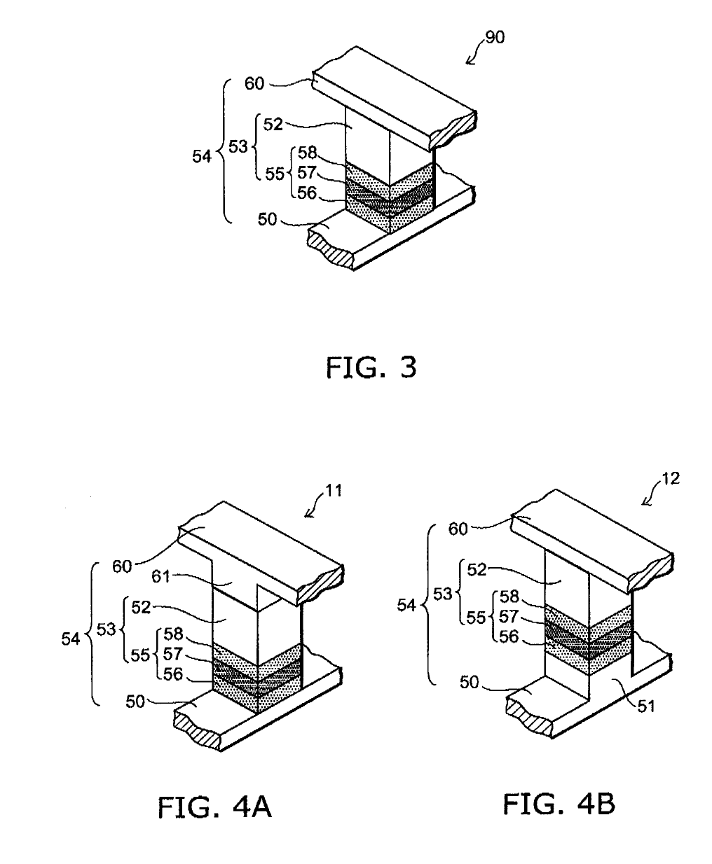

FIG. 3 is a schematic perspective view illustrating a structure of a relevant part of a nonvolatile storage device of a first comparative example.

In a nonvolatile storage device 90 of the first comparative example illustrated in FIG. 3, no T-shaped portions are drawn from the word line 50 and bit line 60 wirings. The stacked structure unit 53 including the recording layer 57 is a structure disposed between the same surfaces which are part of the wirings of the word line 50 and the bit line 60. Otherwise, the configuration is similar to that of the nonvolatile storage device 10 illustrated in FIG. 1, and a description thereof is omitted.

In the nonvolatile storage device 90 of the first comparative example illustrated in FIG. 3, the stacked structure unit 53 including the recording layer 57 is directly connected to the wirings of the word line 50 and the bit line 60 without connecting through the T-shaped portions 51 and 61. Therefore, joule heat occurring in the recording layer 57 by providing an erasing current undesirably dissipates via the wirings of the word line 50 and/or the bit line 60. In other words, the wirings of the word line 50 and/or the bit line 60 undesirably act as heat sinks, requiring a large joule heat to increase the temperature of the recording layer 57 to a temperature necessary to erase the programmed state. Therefore, the erasing current increases and the operation speed decreases.

Conversely, in the nonvolatile storage device 10 according to this embodiment described above, the distance between the recording layer 57 and the wirings can be increased by providing T-shaped portions 51 and 61 on the word line 50 and the bit line 60, thus preventing the wirings from acting as heat sinks. The joule heat necessary to increase the temperature for erasing, for example, can be decreased thereby. As a result, the consumed current can be reduced, and the operation speed can be increased.

Thus, the nonvolatile storage device 10 according to this embodiment decreases the operating current and realizes a high-speed operation.

Although the T-shaped portions 51 and 61 are provided on the word line 50 and the bit line 60, respectively, in the nonvolatile storage device 10 illustrated in FIG. 1, the nonvolatile storage device according to this embodiment may include a T-shaped portion provided on at least one of the word line 50 and the bit line 60.

FIGS. 4A and 4B are schematic perspective views illustrating structures of relevant parts of other nonvolatile storage devices according to the first embodiment of the invention.

The T-shaped portion 61 is provided on the bit line 60 in another nonvolatile storage device 11 according to the first embodiment of the invention illustrated in FIG. 4A. Such a structure of the nonvolatile storage device 11 also can prevent wirings from acting as heat sinks, reduce the operating current, and enable a high-speed operation.

The T-shaped portion 51 is provided on the word line 50 in another nonvolatile storage device 12 according to the first embodiment of the invention illustrated in FIG. 4B. Such a structure of the nonvolatile storage device 12 also can prevent the wiring from acting as a heat sink, reduce the operating current, and enable a high-speed operation.

Thus, by providing the T-shaped portions 51 and 61 on at least one of the word line 50 and the bit line 60, the wirings can be prevented from acting as heat sinks, the operating current can be reduced, and a high-speed operation is possible.

Although the stacked memory layer unit 55 is disposed on the word line 50 side and the rectifying element 52 is disposed on the bit line 60 side in the nonvolatile storage devices 11 and 12 illustrated in FIGS. 4A and 4B, the invention is not limited thereto. The stacking order (disposition order) of the stacked recording layer unit 55 and the rectifying element 52 is arbitrary.

### FIRST EXAMPLE

A first example of this embodiment will now be described. A nonvolatile storage device 10a of the first example includes the structure of the nonvolatile storage device 10 according to this embodiment illustrated in FIG. 1. First, a method for manufacturing the nonvolatile storage device 10a of this example is described.

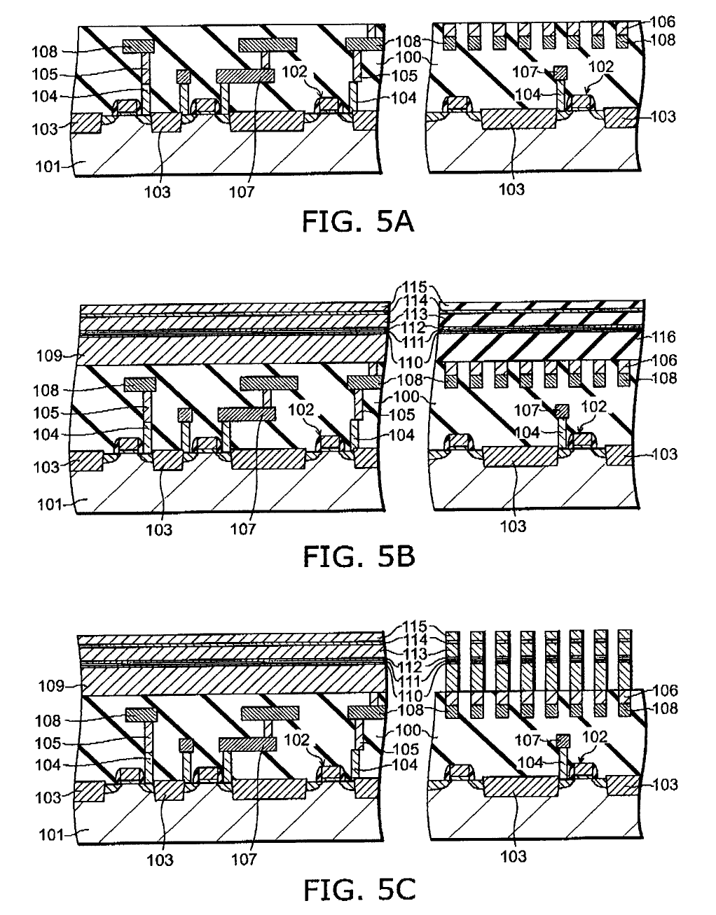

FIGS. 5A to 5C are schematic cross-sectional views in order of the steps, illustrating a method for manufacturing the nonvolatile storage device according to the first example of the invention.

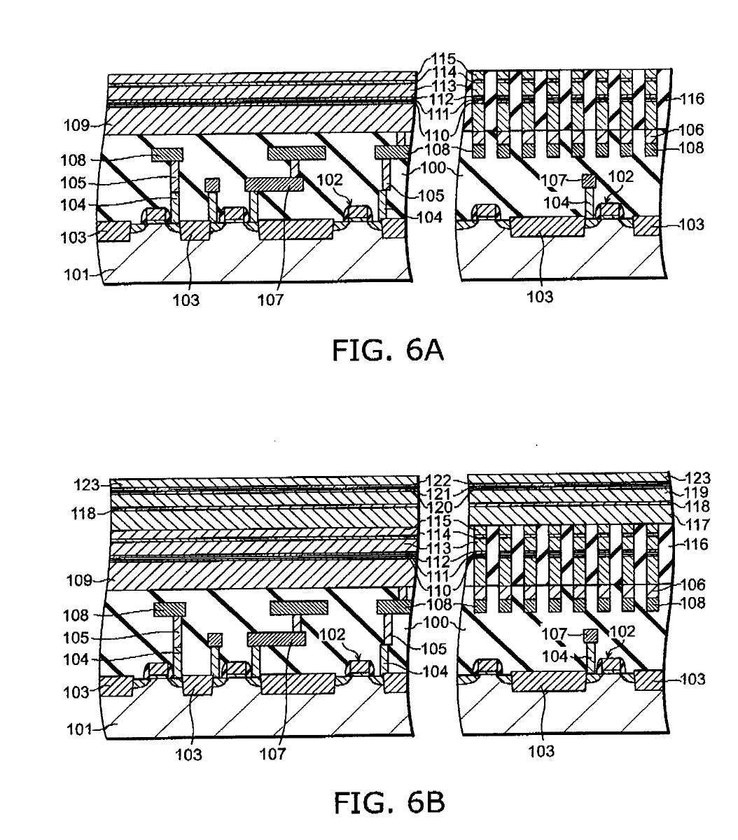

FIGS. 6A and 6B are drawings continuing from FIG. 5C.

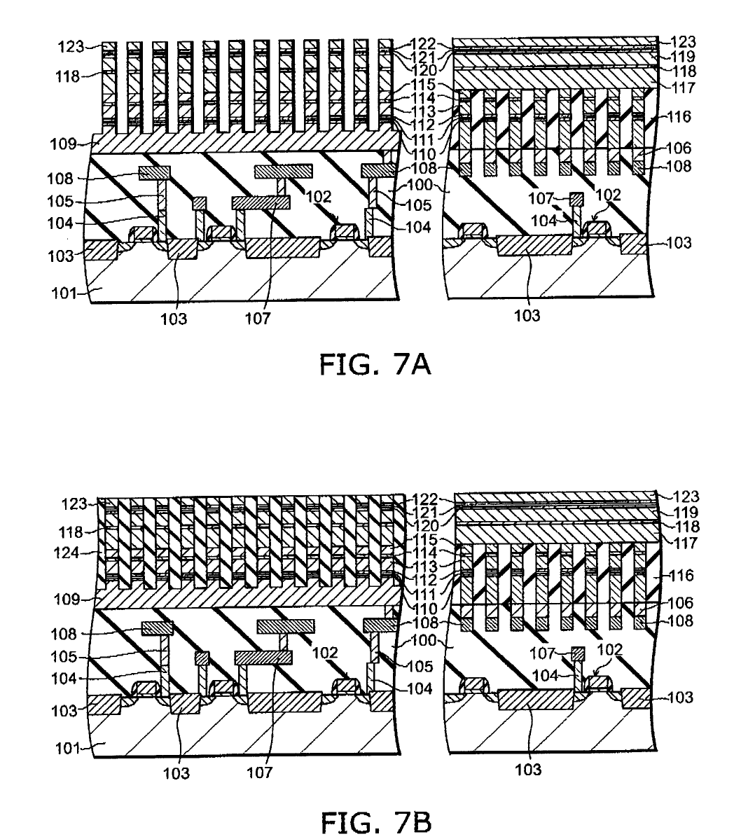

FIGS. 7A and 7B are drawings continuing from FIG. 6B.

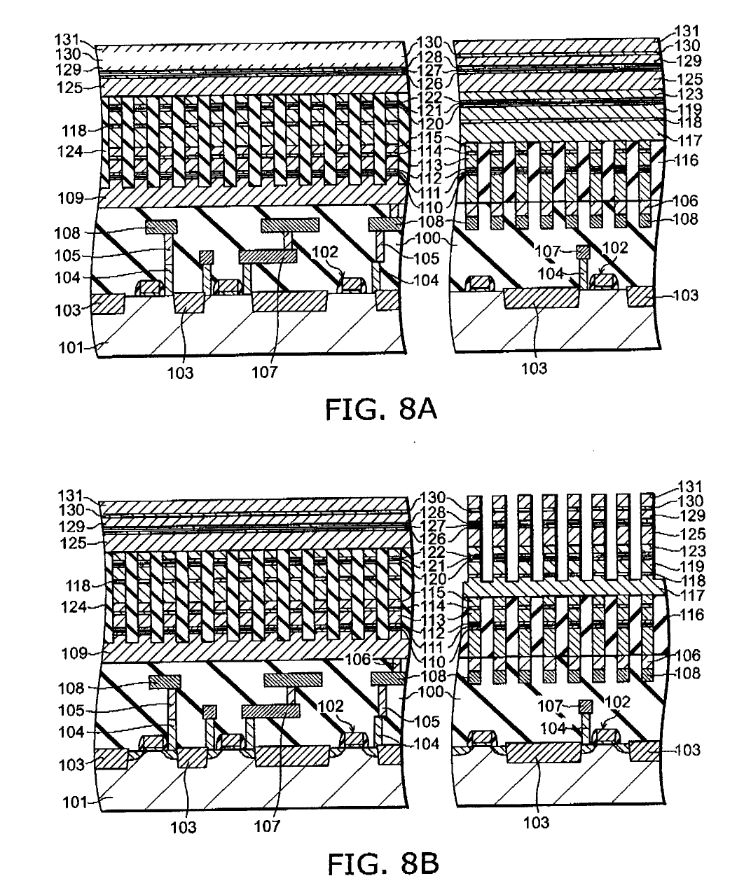

FIGS. 8A and 8B are drawings continuing from FIG. 7B.

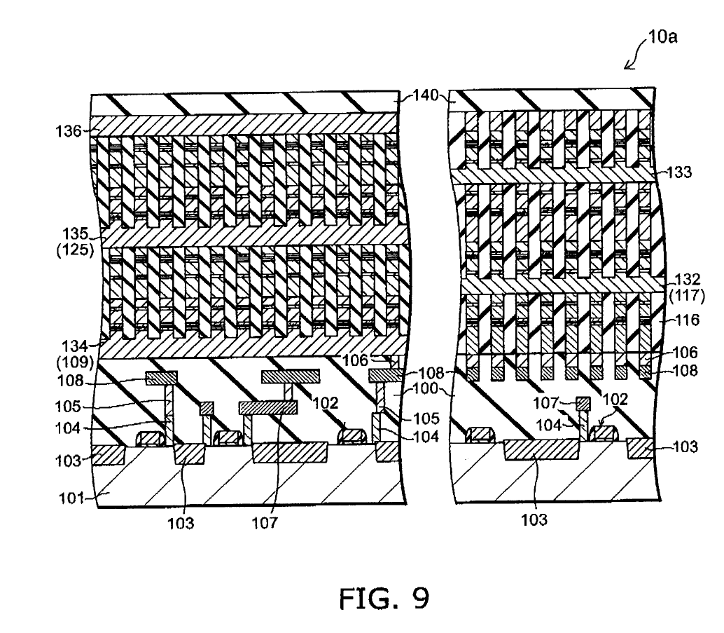

FIG. 9 is a drawing continuing from FIG. 8B.

The left side of each of these drawings is a cross-sectional view in a bit line direction (a cross-sectional view cut along a plane perpendicular to the extension direction of the bit line). The right side of each of these drawings is a cross-sectional view in a word line direction (a cross-sectional view cut along a plane perpendicular to the extension direction of the word line).

First, as illustrated in FIG. 5A, transistors 102 that form a peripheral circuit of a memory region, STIs (Shallow Trench Isolation) 103, contact plugs 104, 105, and 106, M0 wirings (source wirings) 107, M1 wirings (bit wirings) 108, and an insulating layer 100 are formed by known semiconductor manufacturing technology on a semiconductor substrate 101.

Then, as illustrated in FIG. 5B, a tungsten film 109 that forms word lines of the memory elements is formed with a thickness of 150 nm; a titanium nitride film 110 that forms barrier metal is formed with a thickness of 10 nm; a Ti-doped NiOₓ film 111 that forms variable resistance elements (recording layers) is formed with a thickness of 5 nm; a titanium nitride film 112 that forms barrier metal is formed with a thickness of 10 nm; an n⁺/n⁻/p⁺ polycrystalline silicon stacked film 113 that forms PIN diodes is formed; a tungsten nitride film 114 that forms barrier metal is formed with a thickness of 10 nm; and a tungsten film 115 that forms a portion of the bit lines is formed with a thickness of 50 nm. The tungsten film 115 subsequently becomes T-shaped portions.

Continuing as illustrated in FIG. 5C, the stacked films 109 to 115 are sequentially patterned by lithography and reactive ion etching.

As illustrated in FIG. 6A, an inter-layer insulating film 116 is filled between the sequentially patterned stacked films 109 to 115, and the configuration is planarized by CMP (Chemical Mechanical Polishing), reactive ion etching, or the like.

Then, as illustrated in FIG. 6B, a tungsten film 117 that forms bit lines is formed with a thickness of 150 nm; a tungsten nitride film 118 that forms barrier metal is formed with a thickness of 10 nm; a p⁺/n⁻/n⁺ polycrystalline silicon stacked film 119 is formed; a titanium nitride film 120 that forms barrier metal is formed with a thickness of 10 nm; a Ti-doped NiO, film 121 that forms resistance change elements is formed with a thickness of 5 nm; a titanium nitride film 122 that forms barrier metal is formed with a thickness of 10 nm; and a tungsten film 123 that forms a portion of the word lines is formed with a thickness of 50 nm.

Continuing as illustrated in FIG. 7A, the stacked films 117 to 123 are sequentially patterned with lithography and reactive ion etching. The inter-layer dielectric film 116, the stacked films 110 to 115 that remains between the inter-layer dielectric films, and a portion of the tungsten film 109 also are collectively patterned. At this time, the tungsten film 109 is patterned in a T-shape by collectively etching about 50 nm of the upper portion. T-shaped portions are formed thereby with a thickness of 50 nm.

As illustrated in FIG. 7B, an inter-layer dielectric film 124 is filled between the collectively processed stacked films, and the configuration is planarized by CMP, reactive ion etching, or the like.

Then, as illustrated in FIG. 8A, a tungsten film 125 that forms word lines is formed with a thickness of 150 nm; a titanium nitride film 126 that forms barrier metal is formed with a thickness of 10 nm; a Ti-doped NiOₓ film 127 that forms resistance change elements is formed with a thickness of 5 nm; a titanium nitride film 128 that forms barrier metal is formed with a thickness of 10 nm; an n⁺/n⁻/p⁺ polycrystalline silicon stacked film 129 is formed; a tungsten nitride film 130 that forms barrier metal is formed with a thickness of 10 nm; and a tungsten film 131 that forms a portion of the bit lines is formed with a thickness of 50 nm. The tungsten film 131 subsequently becomes T-shaped portions.

Continuing as illustrated in FIG. 8B, the stacked films 125 to 131 are sequentially patterned with lithography and reactive ion etching. The inter-layer dielectric film 124, the stacked films 118 to 123 that remains between the inter-layer dielectric films, and a portion of the tungsten film 117 also are collectively patterned. At this time, the tungsten film 117 is patterned in a T-shape by collectively etching about 50 nm of the upper portion. T-shaped portions are formed thereby with a thickness of 50 nm.

As illustrated in FIG. 9, the nonvolatile storage device 10a is formed to include stacked structure units that form memory cells provided between word lines and bit lines and stacked on one another in four layers. To illustrate all films in a drawing would result in complexity, and therefore the bit lines BL1 (132) and BL2 (133), the word lines WL1 (134), WL2 (135), and WL3 (136), and the inter-layer dielectric films 137 to 140 are illustrated.

The number of layers of the nonvolatile storage device 10a of this example is not confined to four layers; and more than four layers may be stacked. In such a case, the manufacturing may be performed by a method similar to that described above.

Thus, the method for manufacturing the nonvolatile storage device according to this embodiment reduces the operating current and realizes a high-speed operation.

A method similar to that described above also may be used to manufacture nonvolatile storage devices 11a and 12a (not illustrated) of other examples, including the respective structures illustrated in FIGS. 4A and 4B. Namely, in the case where, for example, the tungsten films 109 and 117 are not collectively processed, the T-shaped portions on the word line side are not formed; and the nonvolatile storage device 11a including the structure illustrated in FIG. 4A can be constructed. Additionally, in the case where, for example, the tungsten films 115 and 131 are not formed, the T-shaped portions on the bit line side are not formed; and the nonvolatile storage device 12a including the structure illustrated in FIG. 4B can be constructed.

In the case where, for example, the tungsten films 109, 117, 115, and 131 are not formed, the T-shaped portions on both the word line side and the bit line side are not formed; and a nonvolatile storage device 90a (not illustrated) of the first comparative example illustrated in FIG. 3 can be constructed.

The characteristics of the nonvolatile storage devices 10a, 11a, and 12a of this example, and the nonvolatile storage device 90a of the first comparative example will now be described.

TABLE 1 illustrates the programming speed, erasing speed, programming current, and erasing current of these nonvolatile storage devices.

TABLE 1

| | | | | FIRST COMPARATIVE |
|---|---|---|---|---|
| | FIRST EXAMPLE | | | EXAMPLE |
| | NONVOLATILE | NONVOLATILE | NONVOLATILE | NONVOLATILE |
| | STORAGE DEVICE 10a | STORAGE DEVICE 11a | STORAGE DEVICE 12a | STORAGE DEVICE 90a |
| STRUCTURE | FIG. 1 | FIG. 4A | FIG. 4B | FIG. 3 |
| PROGRAMMING SPEED | 50 ns | 80 ns | 65 ns | 100 ns |
| ERASING SPEED | 70 ns | 250 ns | 220 ns | 300 ns |
| PROGRAMMING CURRENT | 20 μA | 60 μA | 75 μA | 80 μA |
| ERASING CURRENT | 50 μA | 180 μA | 170 μA | 250 μA |

As illustrated in TABLE 1, each of the nonvolatile storage devices 10a, 11a, and 12a according to this example have faster programming speeds and erasing speeds and lower programming currents and erasing currents in comparison to the nonvolatile storage device 90a of the first comparative example.

These benefits are provided because, for example, during the programming and erasing operations, joule heat occurring in the recording layer 57 in the structure of the first comparative example undesirably dissipates via the wirings of the bit line and the word line to reduce the efficiency; while the T-shaped portions 51 and 61 provided on the word lines and/or the bit lines of the nonvolatile storage devices 10a, 11a, and 12a according to this embodiment can prevent these wirings from acting as heat sinks.

In particular for the nonvolatile storage device 10a in which T-shaped portions are provided on both the word lines and the bit lines, the programming speed and the erasing speed are the fastest, and the programming current and the erasing current are the lowest.

Thus, the nonvolatile storage device and the method for manufacturing the same according to this example reduce the operating current and realize a high-speed operation.

In this example, a Ti-doped NiOₓ film is used as the recording layer 57 (variable resistance element); but the invention is not limited thereto. The recording layer 57 of the nonvolatile storage device according to this embodiment may include any substance in which a resistance state thereof changes due to a voltage applied to both ends. For example, the recording layer 57 may include at least one selected from the group consisting of C, NbOₓ, Cr-doped SrTiO₃₋ₓ, PrₓCa_{y}MnO_{z}, Ti-doped NiOₓ, ZrOₓ, NiOₓ, ZnOₓ, TiOₓ, TiOₓN_{y}, CuOₓ, GdOₓ, CuTeₓ, HfOₓ, ZnMnₓO_{y}, and ZnFeₓO_{y}. Additionally, a material may be used having two or more of such materials mixed. Furthermore, a structure of multiply stacked layers of such materials may be used.

Titanium nitride was used for the electrode of this example; but the invention is not limited thereto. Any conductive material that does not react with the recording layer 57 of the nonvolatile storage device according to this embodiment and compromise the variable resistance properties may be used. The electrode may include, for example, titanium nitride, tungsten nitride, titanium aluminum nitride, tantalum nitride, titanium silicide nitride, tantalum carbide, titanium silicide, tungsten silicide, cobalt silicide, nickel silicide, nickel platinum silicide, platinum, ruthenium, platinum-rhodium, iridium, and the like.

The rectifying element 52 provided between the recording layer 57 and at least one of the first wiring and the second wiring may include a semiconductor such as silicon, germanium, and the like; and may include a metal oxide semiconductor such as NiO, TiO, CuO, InZnO, and the like.

### SECOND EXAMPLE

A second example of the first embodiment of the invention will now be described. The nonvolatile storage device of the second example is an example of a phase change memory element. The stacked structure unit 53 includes a stacked memory layer unit 55 that includes a material in which a resistance changes due to a phase change, and a heater material. The stacked structure unit 53 is provided between a word line and a bit line that have T-shaped portions.

That is, a nonvolatile storage device 10b of the second example includes a structure based on the structure illustrated in FIG. 1. Namely, the nonvolatile storage device 10b includes stacked memory cells having a shared bit line/word line structure in which word lines/bit lines are shared by cells above and below. The stacked structure unit 53, which includes the rectifying element 52, the recording layer 57, and a heater (which also may act, for example, as a barrier metal), is disposed between the T-shaped portions 51 and 61 of the wirings (bit lines or word lines) above and below. As described above, the number of the bit lines and the word lines is arbitrary, and the number of component memory layers stacked on one another also is arbitrary.

A method for manufacturing the nonvolatile storage device 10b of this example will now be described.

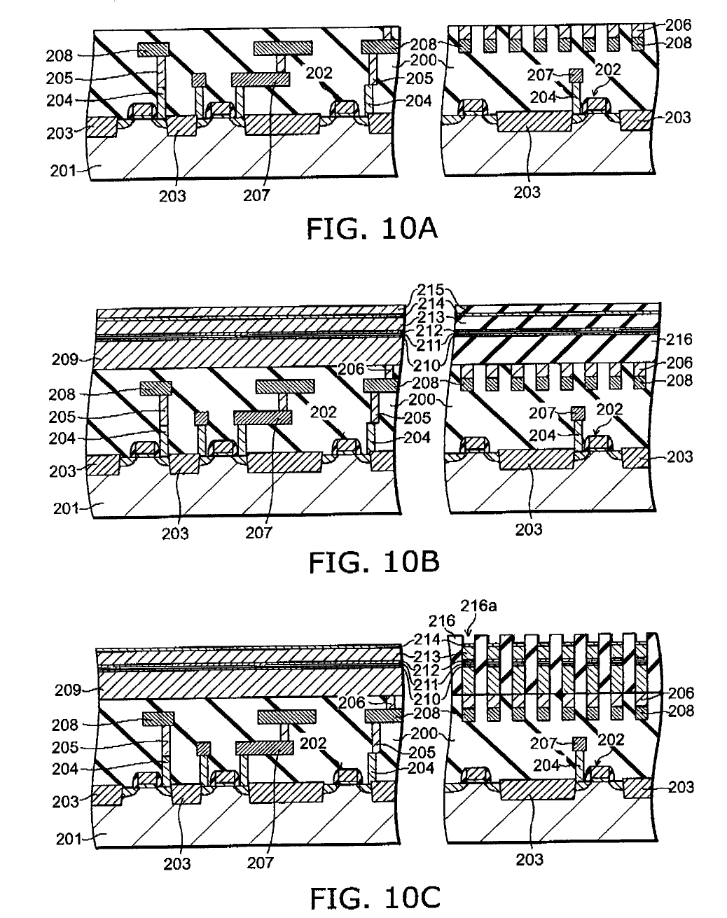

FIGS. 10A to 10C are schematic cross-sectional views in order of the steps, illustrating the method for manufacturing the nonvolatile storage device according to the second example of the invention.

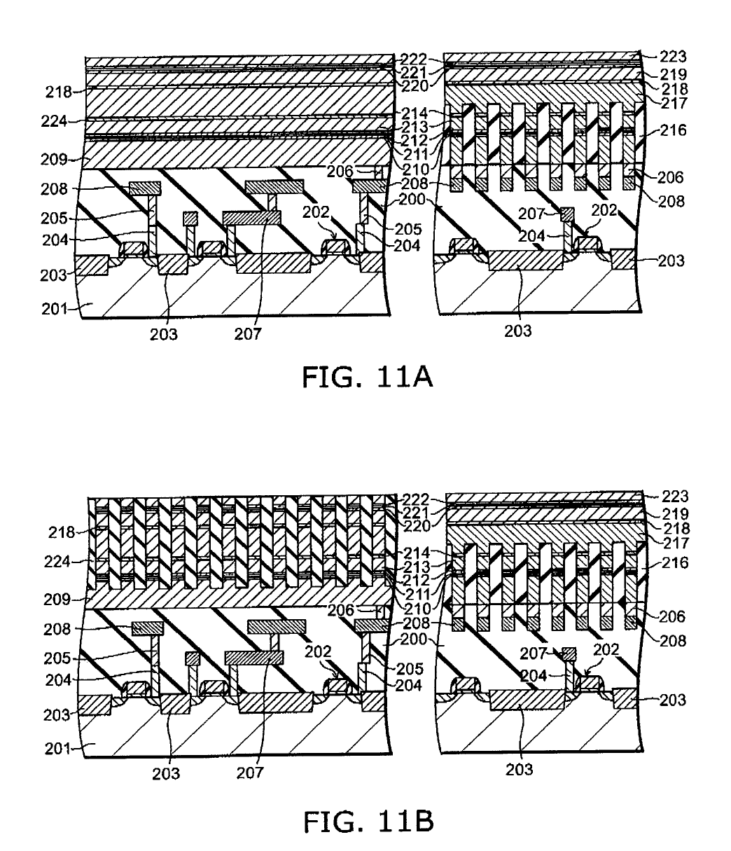

FIGS. 11A and 11B are drawings continuing from FIG. 10C.

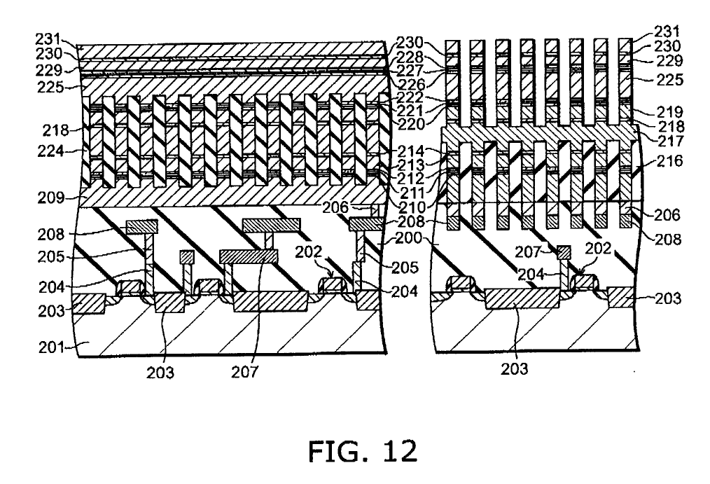

FIG. 12 is a drawing continuing from FIG. 11B.

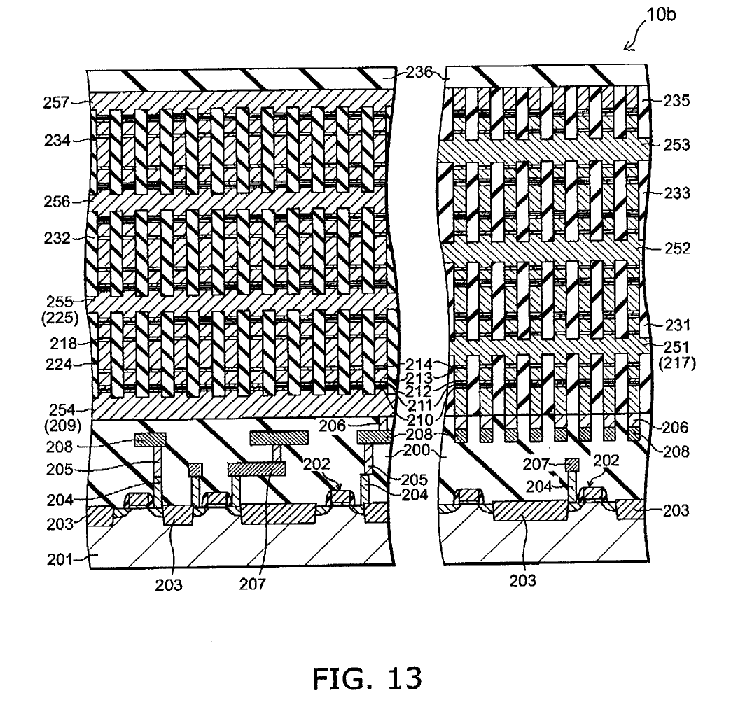

FIG. 13 is a drawing continuing from FIG. 12.

First, as illustrated in FIG. 10A, transistors 202 that form a peripheral circuit of a memory region, STIs (Shallow Trench Isolation) 203, contact plugs 204, 205, and 206, M0 wirings 207, M1 wirings 208, and an insulating layer 200 are formed with known semiconductor manufacturing technology on a semiconductor substrate 201.

Then, as illustrated in FIG. 10B, a tungsten film 209 that forms word lines of the memory elements is formed with a thickness of 200 nm; a GeₓSb_{y}Te_{z} film 210 that forms resistance change elements (recording layers) is formed with a thickness of 10 nm; a tantalum oxide film 211 that forms heaters is formed with a thickness of 2 nm; a tungsten nitride film 212 that forms barrier metal is formed with a thickness of 10 nm; an n⁺/n⁻/p⁺ polycrystalline silicon stacked film 213 that forms PIN diodes is formed; a tungsten nitride film 214 that forms barrier metal is formed with a thickness of 10 nm; and a silicon nitride film 215 that forms a CMP stopper is formed with a thickness of 50 nm.

Continuing as illustrated in FIG. 10C, the stacked films 209 to 215 are sequentially patterned with lithography and reactive ion etching. An inter-layer dielectric film 216 is then filled between the sequentially patterned stacked films 209 to 215. After the configuration is planarized by CMP technology, the silicon nitride film 215 is selectively removed by wet etching or dry etching to form openings 216a.

As illustrated in FIG. 11A, a tungsten film 217 that forms bit lines is filled into the openings 216a and formed to a thickness of 200 nm above the flat portion. A tungsten nitride film 218 that forms barrier metal is formed with a thickness of 10 nm; a p⁺/n⁻/n⁺ polycrystalline silicon stacked film 219 is formed; a tungsten nitride film 220 that forms barrier metal is formed with a thickness of 10 nm; a tantalum oxide film 221 that forms heaters is formed with a thickness of 2 nm; a GeₓSb_{y}Te_{z} film 222 that forms resistance change elements is formed with a thickness of 10 nm; and a silicon nitride film 223 that forms a CMP stopper is formed with a thickness of 50 nm. The portions of the tungsten film 217 filled into the openings 216a form T-shapes.

Then, as illustrated in FIG. 11B, the stacked films 217 to 223 are sequentially patterned with lithography and reactive ion etching. The inter-layer dielectric film 216 and the stacked films 209 to 214 remains between the inter-layer dielectric films are collectively patterned. An inter-layer dielectric film 224 is filled between the collectively patterned stacked films 217 to 223 and 209 to 214, and the configuration is planarized by CMP technology. During the collective patterning described above, the tungsten film 209 is processed in a T-shape by collectively etching about 100 nm of the upper portion. T-shaped portions are formed thereby with a thickness of 50 nm.

Continuing as illustrated in FIG. 12, openings are made by selective etching in the silicon nitride film 223. A tungsten film 225 that forms word lines is filled into the openings and formed to a thickness of 200 nm above the flat portion. A GeₓSb_{y}Te_{z} film 226 that forms resistance change elements is formed with a thickness of 5 nm; a tantalum oxide film 227 that forms heaters is formed with a thickness of 2 nm; a tungsten nitride film 228 that forms barrier metal is formed with a thickness of 10 nm; an n⁺/n⁻/p⁺ polycrystalline silicon stacked film 229 is formed; a tungsten nitride film 230 that forms barrier metal is formed with a thickness of 10 nm; and a silicon nitride film 231 that forms a CMP stopper is formed with a thickness of 50 nm. Then, the stacked films 225 to 231 are sequentially patterned with lithography and reactive ion etching, and the inter-layer dielectric film 224 and the stacked films 217 to 223 filled by the inter-layer dielectric film are collectively patterned. At this time, the tungsten film 217 can be processed in a T-shape by collectively etching about 100 nm of the upper portion. T-shaped portions are formed thereby with a thickness of 50 nm.

Then, similar manufacturing steps are repeated to stack resistance change memory cells.

Thus, the nonvolatile storage device 10b having the six stacked layers illustrated in FIG. 13 is constructed. To illustrate all films in a drawing would result in complexity, and therefore the bit lines BL1 (251), BL2 (252), and BL3 (253), the word lines WL1 (254), WL2 (255), WL3 (256), and WL4 (257), and the inter-layer insulating films 231 to 236 are illustrated.

Nonvolatile storage devices having more than six layers may be constructed by similar methods.

A method similar to that described above also may be used to manufacture nonvolatile storage devices 11b and 12b (not illustrated) of other examples, including structures based on the structures illustrated in FIG. 4A and FIG. 4B, respectively. Namely, in the case where, for example, the tungsten films 209 and 225 are not collectively processed, the T-shaped portions on the word line side are not formed; and the nonvolatile storage device 11b including the structure illustrated in FIG. 4A can be constructed. Additionally, in the case where, for example, the silicon nitride films 215, 223, and 231 are not formed, openings are not made and therefore the T-shaped portions on the bit line side are not formed; and the nonvolatile storage device 12b including the structure illustrated in FIG, 4B can be constructed.

### SECOND COMPARATIVE EXAMPLE

In the case where, for example, tungsten films 209 and 225 and silicon nitride films 215, 223, and 231 are not formed, T-shaped portions on both the word line side and the bit line side are not formed; and a nonvolatile storage device 90b (not illustrated) of the second comparative example including the structure of the first comparative example illustrated in FIG. 3 can be constructed.

The characteristics of the nonvolatile storage devices 10b, 11b, and 12b of this example, and the nonvolatile storage device 90b of the second comparative example will now be described. These structures are based on the structures of FIG. 1, FIGS. 4A and 4B, and FIG. 3, and use a GeₓSb_{y}Te_{z} film as the recording layer.

TABLE 2 illustrates the programming speed, erasing speed, programming current, and erasing current of these nonvolatile storage devices.

TABLE 2

| | | | | SECOND |
|---|---|---|---|---|
| | | | | COMPARATIVE |
| | SECOND EXAMPLE | | | EXAMPLE |
| | NONVOLATILE | NONVOLATILE | NONVOLATILE | NONVOLATILE |
| | STORAGE DEVICE 10b | STORAGE DEVICE 11b | STORAGE DEVICE 12b | STORAGE DEVICE 90b |
| STRUCTURE | FIG. 1 | FIG. 4A | FIG. 4B | FIG. 3 |
| PROGRAMMING SPEED | 50 ns | 80 ns | 70 ns | 100 ns |
| ERASING SPEED | 100 ns | 170 ns | 160 ns | 200 ns |
| PROGRAMMING CURRENT | 50 μA | 80 μA | 75 μA | 100 μA |
| ERASING CURRENT | 70 μA | 150 μA | 160 μA | 200 μA |

As illustrated in TABLE 2, each of the nonvolatile storage devices 10b, 11b, and 12b according to this embodiment have faster programming speeds and erasing speeds and lower programming currents and erasing currents in comparison to the nonvolatile storage device 90b of the second comparative example.

These benefits are provided because, for example, during the erasing operation, joule heat occurring in the resistance change elements in the structure of the second comparative example dissipates via the wirings of the bit line and the word line to reduce the efficiency; while the T-shaped portions 51 and 61 provided on the word lines and/or the bit lines of the nonvolatile storage devices 10b, 11b, and 12b according to this embodiment can prevent these wirings from acting as heat sinks.

Particularly for the nonvolatile storage device 10b in which T-shaped portions 51 and 61 are provided on both the word lines 50 and the bit lines 60, the programming speed and the erasing speed are the fastest, and the programming current and the erasing current are the lowest.

Thus, the nonvolatile storage device and the method for manufacturing the same according to this example reduce the operating current and realize a high-speed operation.

A GST film (GeₓSb_{y}Te_{z} film) is used for the resistance change element (recording layer 57) of this example; but the invention is not limited thereto. The recording layer 57 of the nonvolatile storage device according to this example may include any substance in which a resistance state thereof changes due to a joule heat occurring due to a voltage applied to both ends. The recording layer 57 may include, for example, N-doped GST or O-doped GST in which a dopant is added to a chalcogenide GST, GeₓSb_{y}, InₓGe_{y}Te_{z}, and the like.

The heater of this example includes tantalum oxide; but the invention is not limited thereto. The heater of the nonvolatile storage device according to this embodiment may include niobium oxide, titania, and the like. It is also possible not to use a heater; and a barrier metal may simultaneously act as the heater.

The electrode of the invention includes tungsten nitride; but the invention is not limited thereto. The electrode of the nonvolatile storage device according to this embodiment may include any material that does not react with the heater and compromise the variable resistance properties, such as, for example, titanium nitride, titanium aluminum nitride, tantalum nitride, titanium silicide nitride, tantalum carbide, titanium silicide, tungsten silicide, cobalt silicide, nickel silicide, nickel platinum silicide, platinum, ruthenium, platinum-rhodium, iridium, and the like.

The rectifying element may include a semiconductor such as silicon, germanium, and the like; and may include a metal oxide semiconductor such as NiO, TiO, CuO, InZnO, and the like.

Although six examples (nonvolatile storage devices 10a, 11a, 12a, 10b, 11b, and 12b) are described above, practice of the invention is not confined thereto. Materials and structures, including those of the examples, may be appropriately combined. In such a case, the effects expected of the invention can be provided. That is, the inhibition of the dissipation of joule heat occurring in the resistance change portion is possible; the programming and erasing characteristics can be improved; and a nonvolatile storage device and a method for manufacturing the same can be provided to reduce the operating current and realize a high-speed operation.

### Second Embodiment

A method for manufacturing a nonvolatile storage device according to a second embodiment of the invention will now be described. The method for manufacturing the nonvolatile storage device according to this embodiment includes component memory layers multiply stacked on one another; the component memory layer including: a first wiring (for example, a word line 50) aligned in a first direction (for example, a word line direction); a second wiring (for example, a bit line 60) aligned in a second direction (for example, a bit line direction) non-parallel to, that is, to intersect with, the first direction; and a stacked structure unit that includes a recording layer provided between the first wiring and the second wiring. The method for manufacturing the nonvolatile storage device according to this embodiment is a method for manufacturing the nonvolatile storage device which includes T-shaped portions provided on word lines 50 and/or bit lines 60. A method for forming the T-shaped portions will now be described in detail. Otherwise, known methods may be used.

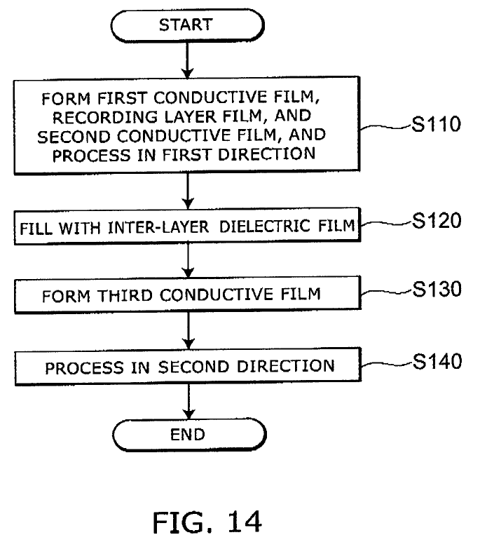

FIG. 14 is a flowchart illustrating the method for manufacturing the nonvolatile storage device according to the second embodiment of the invention.

In the method for manufacturing the nonvolatile storage device according to the second embodiment of the invention illustrated in FIG. 14, first, a first conductive film that forms first wirings, a recording layer film that forms recording layers, and a second conductive film that forms a portion of second wirings are formed on a substrate. The first conductive film, the recording layer film, and the second conductive film are processed into a band configuration aligned in the first direction (step S110).

The substrate may include, for example, transistors 102 that form a peripheral circuit of a memory region, STIs (Shallow Trench Isolation) 103, contact plugs 104, 105, and 106, M0 wirings 107, and M1 wirings 108 provided on a semiconductor substrate 101 as illustrated in FIG. 5A.

Then, as illustrated in FIG. 5B, a tungsten film 109 that forms word lines is formed above the semiconductor substrate 101 as the first conductive film. Thereupon, a Ti-doped NiOₓ film 111 is formed as the recording layer film; and a tungsten film 115 is formed as the second conductive film. At this time, various films other than those described above may be formed as described above in regard to FIG. 5B.

Continuing, for example, as illustrated in FIG. SC, the tungsten film 109, the Ti-doped NiOₓ film 111, and the tungsten film 115 (and other films) are processed into a band configuration in the extension direction of the first wirings (the word line direction, i.e., the first direction).

An inter-layer dielectric film is filled between the first conductive film, the recording layer film, and the second conductive film that were patterned into the band configuration (step S120). After the inter-layer dielectric film is formed between these films that were patterned into the band configuration, the configuration is planarized. For example, the inter-layer dielectric film 116 illustrated in FIG. 6A is formed and flattened.

A third conductive film, which forms another portion of the second wirings, is then formed above the inter-layer dielectric film and above the first conductive film, the recording layer film, and the second conductive film that were filled by the inter-layer dielectric film (step S130). In other words, the tungsten film 117 that forms bit lines is formed as the third conductive film as illustrated in FIG. 6B. Various films that form subsequent component memory layers may then be stacked thereupon.

Then, the recording layer film, the second conductive film, the inter-layer dielectric film, and the third conductive film are collectively patterned into a band configuration aligned in the second direction (step S140). In other words, the recording layer film (for example, a Ti-doped NiOₓ film), the second conductive film (for example, the tungsten film 115), the inter-layer dielectric film (for example, the inter-layer dielectric film 116), and the third conductive film (for example, the tungsten film 117) are collectively processed into a band configuration aligned in the second direction (bit line direction) as illustrated in FIG. 7A.

T-shaped portions are thereby formed by the tungsten film 117 and the tungsten film 115 which form bit lines.

Thus, the nonvolatile storage device 11 according to the embodiment of the invention can be formed in which the T-shaped portion 61 is provided on the bit line 60 as illustrated in FIG. 4A.

By similarly repeating the steps described above, a nonvolatile storage device including component memory layers multiply stacked on one another can be formed in which T-shaped portions 61 are provided on bit lines 60.

Thus, the method for manufacturing the nonvolatile storage device according to this embodiment reduces the operating current and realizes a high-speed operation.

### Third Embodiment

In a method for manufacturing a nonvolatile storage device according to this embodiment, the T-shaped portions are formed by a method different than that of the second embodiment described above. This method for forming the T-shaped portions will now be described in detail. Otherwise, known methods may be used.

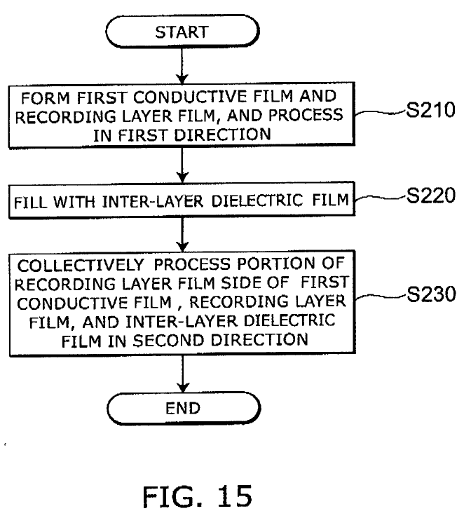

FIG. 15 is a flowchart illustrating the method for manufacturing the nonvolatile storage device according to the third embodiment of the invention.

In the method for manufacturing the nonvolatile storage device according to the third embodiment of the invention illustrated in FIG. 15, first, a first conductive film that forms first wirings, and a recording layer film that forms recording layers are formed on a substrate. The first conductive film and the recording layer film are patterned into a band configuration aligned in the first direction (step S210).

The substrate may be, for example, the semiconductor substrate 101 illustrated in FIG. 5A.

Then, as illustrated in FIG. 5B, the tungsten film 109 is formed above the semiconductor substrate 101 as the first conductive film. Thereupon, the Ti-doped NiO film 111 is formed as the recording layer film. At this time, various films other than those described above may be formed as described above in regard to FIG. 5B. These films are then patterned into a band configuration in the extension direction of the first wirings (word line direction).

An inter-layer dielectric film is filled between the first conductive film and the recording layer film that were patterned into the band configuration (step S220). After the inter-layer dielectric film is formed between the first conductive film and the recording layer film that were patterned into the band configuration, the resulting configuration is flattened. For example, the inter-layer dielectric film 116 illustrated in FIG. 6A is formed and flattened.

Continuing, a portion on the recording layer side of the first conductive film, the recording layer film, and the inter-layer dielectric film are collectively patterned into a band configuration aligned in the second direction (step S230). Namely, a portion on the recording layer film 111 side of the tungsten film 109 (first conductive film), the recording layer film 111, and the inter-layer dielectric film 116 are collectively processed along the second direction (bit line direction) as illustrated in FIG. 7A.

At this time, as illustrated in FIG. 7A, the stacked films 117 to 123, the stacked films 110 to 115, and the portion of the tungsten film 109 can be collectively processed, in other words, at least the second conductive film that forms the second wirings is collectively processed, together with the portion on the recording layer side of the first conductive film, the recording layer film and the inter-layer dielectric film into a band configuration aligned in the second direction.

Thus, T-shaped portions can be formed on the tungsten film 109 that forms word lines.

That is, the nonvolatile storage device 12 according to the embodiment of the invention can be formed in which the T-shaped portion 51 is provided on the word line 50 as illustrated in FIG. 4B.

By similarly repeating the steps described above, a nonvolatile storage device including component memory layers multiply stacked on one another can be formed in which T-shaped portions 51 are provided on word lines 50.

Thus, the method for manufacturing the nonvolatile storage device according to this embodiment reduces the operating current and realizes a high-speed operation.

As described above, T-shaped portions can be provided on each of the word lines and each of the bit lines by the method for manufacturing the nonvolatile storage device according to the second and third embodiments. However, as illustrated in FIG. 5A to FIG. 9, methods for manufacturing the nonvolatile storage device according to the second and third embodiments may be combined to provide T-shaped portions on both the word lines and the bit lines.

In other words, the method for manufacturing the nonvolatile storage device according to this embodiment of the invention, the nonvolatile storage device including component memory layers multiply stacked on one another, the component memory layer including a first wiring aligned in a first direction, a second wiring aligned in a second direction non-parallel to, that is, to intersect with, the first direction, and a stacked structure unit including a recording layer provided between the first wiring and the second wiring, may include: a step that forms a first conductive film that forms the first wiring, a recording layer film that forms the recording layers, and a second conductive film that forms a portion of the second wiring on a substrate, and processes the first conductive film, the recording layer film, and the second conductive film into a band configuration aligned in the first direction; a step that fills an inter-layer dielectric film between the first conductive film, the recording layer film, and the second conductive film processed into the band configuration; a step that forms a third conductive film that forms another portion of the second wiring above the inter-layer insulating film and above the first conductive film, the recording layer film, and the second conductive film that were filled by the inter-layer dielectric film; and a step that collectively processes a portion on the recording layer side of the first conductive film, the recording layer film, the second conductive film, and the inter-layer dielectric film into a band configuration aligned in the second direction.

### Fourth Embodiment

A method for manufacturing a nonvolatile storage device according to this embodiment forms the T-shaped portions by yet a different method. This method for forming the T-shaped portions will now be described in detail. Otherwise, known methods may be used.

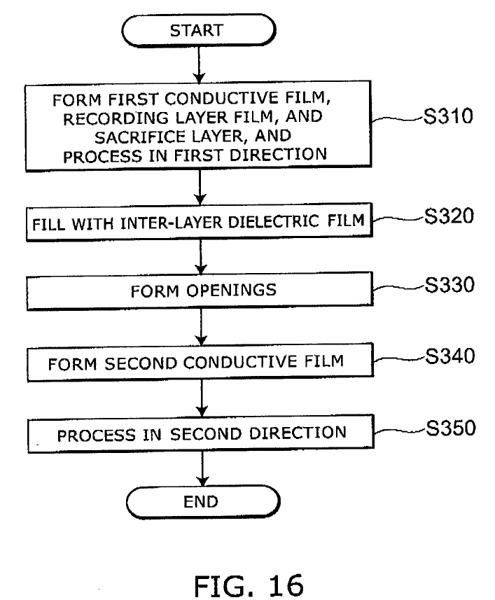

FIG. 16 is a flowchart illustrating the method for manufacturing the nonvolatile storage device according to the fourth embodiment of the invention.

In the method for manufacturing the nonvolatile storage device according to the fourth embodiment of the invention illustrated in FIG. 16, first, a first conductive film that forms first wirings, a recording layer film that forms recording layers, and a sacrificial layer are formed on a substrate. The first conductive film, the recording layer film, and the sacrificial layer are processed into a band configuration aligned in the first direction (step S310).

The substrate may be, for example, the semiconductor substrate 201 illustrated in FIG. 10A. Then, as illustrated in FIG. 10B, the tungsten film 209 is formed above the semiconductor substrate 201 as the first conductive film. Thereupon, the GeₓSb_{y}Te_{z} film 210 is formed as the recording layer film; and the silicon nitride film 215 is formed as the sacrificial layer. These films are then processed into a band configuration in the extension direction of the first wirings (the first direction, and for example, the word line direction). As illustrated in FIG. 10B, stacked films 209 to 215 also can be stacked.

An inter-layer dielectric film is filled between the first conductive film, the recording layer film, and a sacrificial layer that were patterned into the band configuration (step S320). After the inter-layer dielectric film is formed between the first conductive film, the recording layer film, and the sacrificial layer that were processed into the band configuration, the resulting configuration is flattened. For example, the inter-layer dielectric film 216 illustrated in FIG. 10C may be used as the inter-layer dielectric film.

Continuing, openings are made by removing the sacrificial layer (step S330). For example, the openings 216a illustrated in FIG. 10C are made.

A second conductive film (for example, the tungsten film 217 illustrated in FIG. 11A that forms the second wirings is formed to fill the openings 216a by covering above the inter-layer dielectric film and above the first conductive film and the recording layer film that were filled by the inter-layer dielectric film (step S340).

Then, the recording layer film, the inter-layer dielectric film, and the second conductive film are collectively processed into a band configuration aligned in a second direction (for example, the bit line direction) (step S350). At this time, as illustrated in FIG. 11B, the stacked films 209 to 214 and the stacked films 217 to 223 may be collectively processed sequentially.

Thus, T-shaped portions can be formed on the tungsten films 217 that form bit lines.

That is, the nonvolatile storage device 11 according to the embodiment of the invention can be formed in which the T-shaped portion 61 is provided on the bit line 60 as illustrated in FIG. 4A.

By similarly repeating the steps described above, a nonvolatile storage device including component memory layers 54 multiply stacked on one another can be formed in which T-shaped portions 61 are provided on bit lines 60.

Thus, the method for manufacturing the nonvolatile storage device according to this embodiment reduces the operating current and realizes a high-speed operation.

Although an example using a phase change recording layer is illustrated in FIGS. 10A to 13, any material may be used in which the resistance change recording layer described in the first example is provided.

As illustrated in FIGS. 10A to 13, the method for manufacturing the nonvolatile storage device according to this embodiment and the method for manufacturing the nonvolatile storage device according to the third embodiment described above may be combined and practiced simultaneously.

In other words, the method for manufacturing the nonvolatile storage device according to the embodiment of the invention, the nonvolatile storage device including component memory layers multiply stacked on one another, the component memory layer including a first wiring aligned in a first direction, a second wiring aligned in a second direction non-parallel to, that is, to intersect with, the first direction, and a stacked structure unit including a recording layer provided between the first wiring and the second wiring, may include: a step that forms a first conductive film that forms the first wiring, a recording layer film that forms the recording layers, and a sacrificial layer on a substrate, and processes the first conductive film, the recording layer film, and the sacrificial layer into a band configuration aligned in the first direction; a step that fills an inter-layer dielectric film between the first conductive film, the recording layer film, and the sacrificial layer processed into the band configuration; a step that makes openings by removing the sacrificial layer; a step that forms a second conductive film that forms the second wiring by filling the openings to cover above the inter-layer dielectric film and above the first conductive film and the recording layer that were filled by the inter-layer dielectric film; and a step that collectively processes a portion on the recording layer side of the first conductive film, the recording layer film, the inter-layer dielectric film, and the second conductive film into a band configuration aligned in the second direction.

These methods also provide a method for manufacturing the nonvolatile storage device that reduces the operating current and realizes a high-speed operation.

### Fifth Embodiment

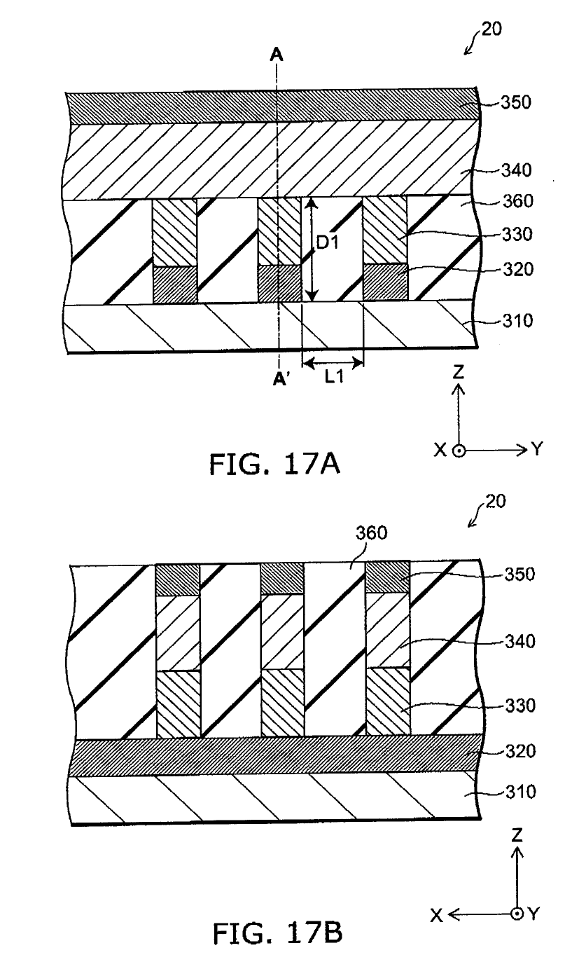

FIGS. 17A and 17B are schematic cross-sectional views illustrating the configuration of a nonvolatile storage device according to a fifth embodiment of the invention.

FIG. 17A is a cross-sectional view cut along a plane perpendicular to the extension direction of a first wiring 320. FIG. 17B is a cross-sectional view along line A-A′ of FIG. 17A, and is a cross-sectional view cut along a plane perpendicular to the extension direction of a second wiring 350.

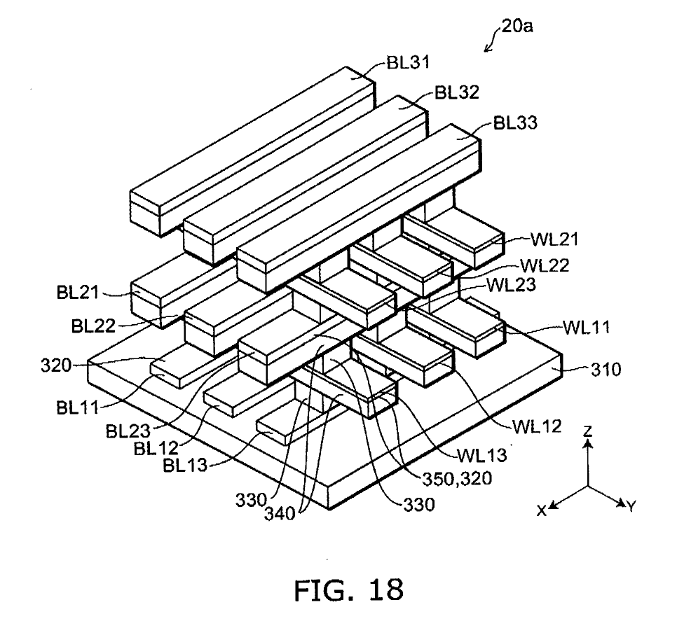

FIG. 18 is a schematic perspective view illustrating the configuration of another nonvolatile storage device according to the fifth embodiment of the invention.

As illustrated in FIGS. 17A and 17B, a nonvolatile storage device 20 according to this embodiment includes a substrate 310, the first wiring 320 (for example, a bit line BL) provided on a major surface of the substrate 310 and aligned in the first direction, the second wiring 350 (for example, a word line WL) aligned in a second direction non-parallel to the first direction, a recording unit 330 disposed between the first wiring 320 and the second wiring 350, and a rectifying element layer 340 aligned along a major surface on the recording unit 330 side of the second wiring 350.

The recording unit 330 is a layer that can reversibly transition between a first state and a second state having a different resistance than that of the first state due to a current supplied via the first wiring 320 and the second wiring 350. In other words, the recording unit 330 is a layer in which a resistance changes due to at least one of an electric field applied and a current provided by the first wiring 320 and the second wiring 350. The recording unit 330 includes, for example, a recording layer described below.

Here, “major surface” refers to a plane perpendicular to a direction in which the first wiring 320, the recording unit 330, and the second wiring 350 are stacked.

The case is assumed where the first direction and the second direction are mutually orthogonal. A Z-axis direction is assumed to the direction orthogonal to an X-axis direction and a Y-axis direction, where the X-axis direction is the first direction and the Y-axis direction is the second direction. In this case, the first wiring 320, the recording unit 330, and the second wiring 350 are stacked in the Z-axis direction; and the major surface of the substrate 310 lies in an X-Y plane.

A barrier layer may be provided between the rectifying element layer 340 and the second wiring 350 to prevent the diffusion of elements therebetween.

Contact plugs, not illustrated, are provided on an exterior with respect to the position of the recording units 330 in the wiring extension direction of wirings L (word lines WL and bit lines BL). The contact plugs are connected to a peripheral circuit including a reading/programming circuit and the like (not illustrated) for programming and reading data. A current passes through the contact plugs and the wirings L (word line WL and bit line BL) and flows in the recording unit 330. Various operations such as programming and erasing of the recording unit 330 can be performed thereby.

Another nonvolatile storage device 20a illustrated in FIG. 18 is a multi-layered nonvolatile storage device including four layers of recording units 330 stacked in a stacking direction (Z-axis direction). A wiring L (word line WL or bit line BL) is shared between each layer. Thus, even in the case where wirings are shared between adjacent cells above and below or between distal cells above and below, it is possible to perform unique operations on each cell by varying a voltage applied to a different wiring Lt (a bit line BL when the wiring L is a word line WL, and a word line WL when the wiring L is a bit line BL) that is connected to the cell.

The number of stacking of the recording unit 330 is arbitrary.

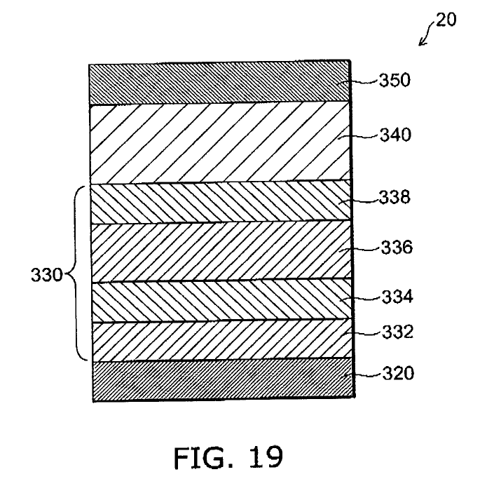

FIG. 19 is another schematic cross-sectional view illustrating the configuration of the nonvolatile storage device according to the fifth embodiment of the invention.

Namely, FIG, 19 illustrates the configuration of the recording unit 330.

Referring to FIG. 19 from the bit line BL sequentially upwards the recording unit 330 includes, for example, a stacked structure in which a heater layer 332, an electrode layer 334, a recording layer 336, and an electrode layer 338 are stacked. The recording unit 330 and the rectifying element layer 340 are provided between the bit line BL and the word line WL.

Although the recording unit 330 is provided on the bit line BL side and the rectifying element layer 340 is provided on the word line WL side in FIG. 19, the recording unit 330, as described below, may be provided on the word line WL side, and the rectifying element layer 340 may be provided on the bit line BL side. In the case where the stacked structure unit including the bit line BL, the recording unit 330, and the word line WL is multiply stacked in a direction perpendicular to the layers as illustrated in FIG. 19, the stacking order of the recording unit 330 and the rectifying element layer 340 is arbitrary; and the stacking order may be the same or may be changed depending on the layers to be stacked.

The electrode layers 334 and 338 are provided to enable electrical connection to the recording layer 336, and are provided as necessary. The electrode layers 334 and 338 may also function as, for example, a barrier layer to prevent diffusion, etc., of elements between the recording layer 336 and the structural components above and below.

In this specific example, the heater layer 332 is a thin, high-resistance film provided on the cathode side (for example, the bit line BL side) of the recording layer 336 for efficiently heating the recording layer 336 during a reset (erasing) operation. In such a case, a barrier layer may be provided between the heater layer 332 and the bit line BL. The heater layer 332 may be provided as necessary or may be omitted.

In the nonvolatile storage device 20 according to this embodiment, a combination of electrical potentials applied to the first wiring 320 and the second wiring 350 changes the voltage applied to each recording unit 330. Information can be recorded and erased by the characteristics (for example, the resistance value) of the recording unit 330 at that time. Therefore, the recording layer 336 may include any material in which a characteristic changes due to an applied voltage. Examples of such materials include, for example, a phase change layer that can reversibly transition between a crystalline state (for example, a first state) and an amorphous state (for example, a second state) due to an applied voltage, a variable resistance layer having a resistance value that can reversibly transition, etc.

Specific examples of such materials include, for example, chalcogenide (compounds including group VIB elements such as Se and Te) variable resistance materials that change between a crystalline state and an amorphous state due to an applied voltage. The material used for the recording layer 336 is further described below.

The rectifying element layer 340 has rectifying properties and is provided to give a directionality to the current applied to the recording unit 330. The rectifying element layer 340 may include, for example, a Zener diode, a PN junction diode, a Schottky diode, and the like. The material used for the rectifying element layer 340 is further described below.

In this specific example, the rectifying element layer 340 extends along a major surface on the recording unit 330 side of the second wiring 350. However, the rectifying element layer 340 may extend along a major surface on the recording unit 330 side of the first wiring 320. In other words, in this embodiment, the rectifying element layer 340 extends along a major surface on the recording unit 330 side of the wiring L, i.e., one of the first wiring 320 and the second wiring 350.

For example, the rectifying element layer 340 of the nonvolatile storage device 20a illustrated in FIG. 18 is provided in both forms. Namely, in the first layer and the third layer, the rectifying element layer 340 extends along the major surface on the recording unit 330 side of the second wiring 350 (word line WL). On the other hand, in the second layer and the fourth layer, the rectifying element layer 340 extends along the major surface of the recording unit 330 side of the first wiring 320 (bit line BL).

The nonvolatile storage devices 20 and 20a according to this embodiment provide effects that (1) fabrication is easy, (2) favorable operating characteristics are obtained, and (3) the power consumption is reduced.

### THIRD COMPARATIVE EXAMPLE

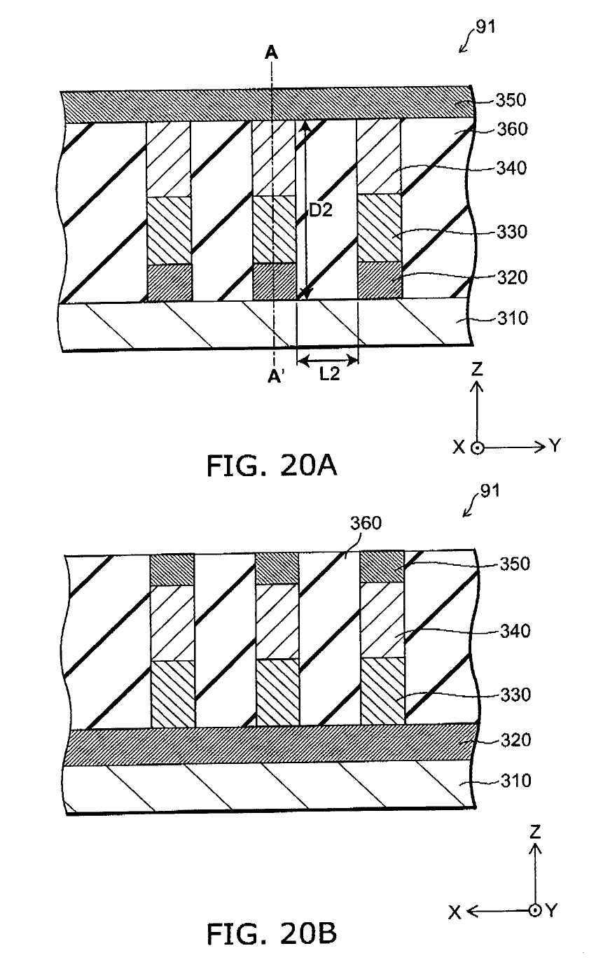

FIGS. 20A and 20B are schematic cross-sectional views illustrating the configuration of a nonvolatile storage device according to a third comparative example.

Namely, FIG. 20A is a cross-sectional view cut along a plane perpendicular to an extension direction of the first wiring 320 of a nonvolatile storage device 91 of the third comparative example. FIG. 20B is a cross-sectional view along line A-A′ of FIG. 20A, and is a cross-sectional view cut along a plane perpendicular to an extension direction of the second wiring 350 of the nonvolatile storage device 91.

In the nonvolatile storage device 91 of the third comparative example illustrated in FIGS. 20A and 20B, the rectifying element layer 340 is disposed between the recording unit 330 and the second wiring 350. In other words, in the nonvolatile storage device 91, the rectifying element layer 340 is provided at a point for each cell, unlike in the nonvolatile storage devices 20 and 20a in which the rectifying element layer 340 extends along the major surface on the recording unit 330 side of the wiring L.

First, the effect of the nonvolatile storage devices 20 and 20a according to this embodiment that (1) fabrication is easy will be described.

For example, in the nonvolatile storage device 20 according to this embodiment and in the nonvolatile storage device 91 of the third comparative example, etching is generally used to form the rectifying element layer 340. In the nonvolatile storage device 20, the rectifying element layer 340 is etched in the Y-axis direction. In the nonvolatile storage device 91, the rectifying element layer 340 is etched in the X-axis direction and the Y-axis direction.

Here, the nonvolatile storage device 20 is different than the nonvolatile storage device 91 in that the rectifying element layer 340 is not etched in the X-axis direction, resulting in fewer etched portions in comparison to the nonvolatile storage device 91. Accordingly, fabrication is relatively easy for the nonvolatile storage device 20 according to this embodiment.

Comparing aspect ratios (ratio of depth to groove width: D/L) of the etched portions in the X-axis direction (portions where an inter-element insulating layer 360 is provided) as illustrated in FIG. 17A and FIG. 20A, a ratio D1/L1 of the nonvolatile storage device 20 is smaller than a ratio D2/L2 of the nonvolatile storage device 91. Therefore, processing by etching is relatively easy for the nonvolatile storage device 20 according to this embodiment.

Thus, the nonvolatile storage device 20 according to this embodiment is easier to construct than the nonvolatile storage device 91 according to the third comparative example.

Next, the effect that (2) favorable operating characteristics can be obtained will now be described. Specifically, three effects are that (A) the operating current is more readily provided, (B) the operating voltage can be reduced, and (C) favorable rectifying properties can be obtained.

First, the effect that (A) the operating current is more readily provided will be described.

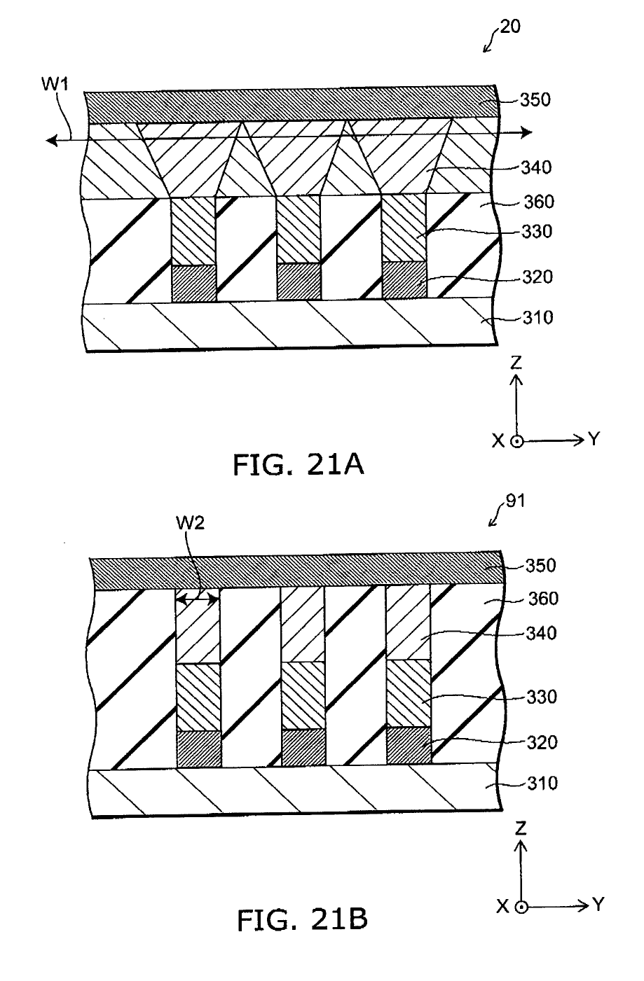

FIG. 21A and 21B are schematic cross-sectional views illustrating configurations of the nonvolatile storage device according to the fifth embodiment of the invention and the nonvolatile storage device of the third comparative example, respectively.

Namely, FIG. 21A is a schematic cross-sectional view along the X-axis direction of the nonvolatile storage device 20 according to this embodiment; and FIG. 21B is a schematic cross-sectional view along the X-axis direction of the nonvolatile storage device 91 of the third comparative example.

In the nonvolatile storage device 91 according to the third comparative example illustrated in FIG. 21B, a width (W2) of the rectifying element layer 340 in the Y-axis direction is relatively small. Therefore, the resistance value of the rectifying element layer 340 is relatively high. Accordingly, current does not flow readily in the recording unit 330.

On the other hand, in the nonvolatile storage device 20 according to this embodiment illustrated in FIG. 21A, a width (a functioning width W1 of the rectifying element) of the rectifying element layer 340 in the Y-axis direction is relatively large. Therefore, the resistance value of the rectifying element layer 340 is relatively low. Accordingly, it is considered that operating current can be provided favorably to the recording unit 330 for programming and the like; and fast and favorable operations can be realized.

Next, the effect that (B) the operating voltage can be reduced will be described.

In the nonvolatile storage device 91 of the third comparative example, the resistance value of the rectifying element layer 340 is relatively high as described above. Therefore, the applied voltage is distributed to the rectifying element layer 340 and the recording unit 330. To this end, a relatively high operating voltage is necessary to perform normal operations such as programming and the like.

On the other hand, in the nonvolatile storage device 20 according to this embodiment, the resistance value of the rectify element layer 340 is relatively low. Therefore, the applied voltage is, comparatively speaking, not readily distributed into the rectifying element layer 340, and is applied almost exclusively to the recording unit 330 (recording layer 336). To this end, a relatively low operating voltage is sufficient. By thus reducing the operating voltage, for example, a circuit for generating a high voltage becomes unnecessary, and downsizing and high integration of elements are possible.

Next, the effect that (C) favorable rectifying properties can be obtained will be described.

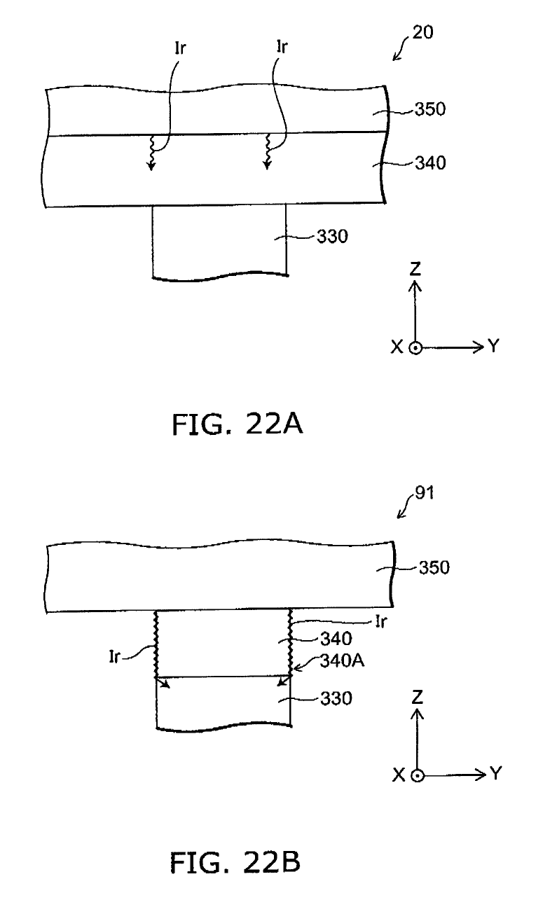

FIG. 22A and 22B are schematic cross-sectional views illustrating operations of the nonvolatile storage device according to the fifth embodiment of the invention and the nonvolatile storage device of the third comparative example, respectively.

Namely, FIG. 22A illustrates the operation of the nonvolatile storage device 20 according to this embodiment, and FIG. 22B illustrates the operation of the nonvolatile storage device 91 of the third example.

As described above, etching is generally used to form the rectifying element layer 340. In the nonvolatile storage device 91 according to the third comparative example illustrated in FIG. 22B, the rectifying element layer 340 is etched in the X-axis direction. Therefore, it is often the case that the defect density is high proximal to a side face 340A (etched surface) of the rectifying element layer 340. As a result, the nonvolatile storage device 91 has a relatively high possibility that a leak current Ir flows along the side face 340A of the rectifying element layer 340 parallel to the X axis when operating and when not operating (in standby).

Thereby, current may flow against the intended current direction when, for example, a large current is provided during erasing. For example, in the case where the rectifying element layer 340 is provided such that current flows in the direction from the second wiring 350 toward the first wiring 320 as illustrated in FIG. 22B, it is considered that a current may flow in the opposite direction from the first wiring 320 toward the second wiring 350. That is, the risk of a stray current is relatively high. It is thereby possible that favorable rectifying properties cannot be obtained.

On the other hand, the rectifying element layer 340 is not etched in the X-axis direction in the nonvolatile storage device 20 according to this specific example illustrated in FIG. 22A. Therefore, the side face 340A (etched surface) parallel to the X axis does not exist. As a result, the risk is low that a leak current Ir will occur in the nonvolatile storage device 91 in comparison to the nonvolatile storage device 20. Accordingly, stray currents are inhibited, and more favorable rectifying properties can be obtained. Thus, the nonvolatile storage device 20 according to this embodiment provides favorable operating characteristics in comparison to the nonvolatile storage device 91 of the third comparative example.

Next, the effect that (3) the power consumption is reduced will be described.

As described above in regard to FIGS. 22A and 22B, in the nonvolatile storage device 91 of the third comparative example, the risk of a leak current Ir is relatively high when operating and when not operating (in standby). Conversely, the risk of a leak current Ir in the nonvolatile storage device 20 according to this embodiment is low in comparison to the nonvolatile storage device 91. Accordingly, the power consumption of the nonvolatile storage device 20 can be reduced in comparison to the nonvolatile storage device 91.

Thus, the nonvolatile storage devices 20 and 20a of this embodiment provide favorable operating characteristics, reduce the power consumption, and can be easily fabricated.

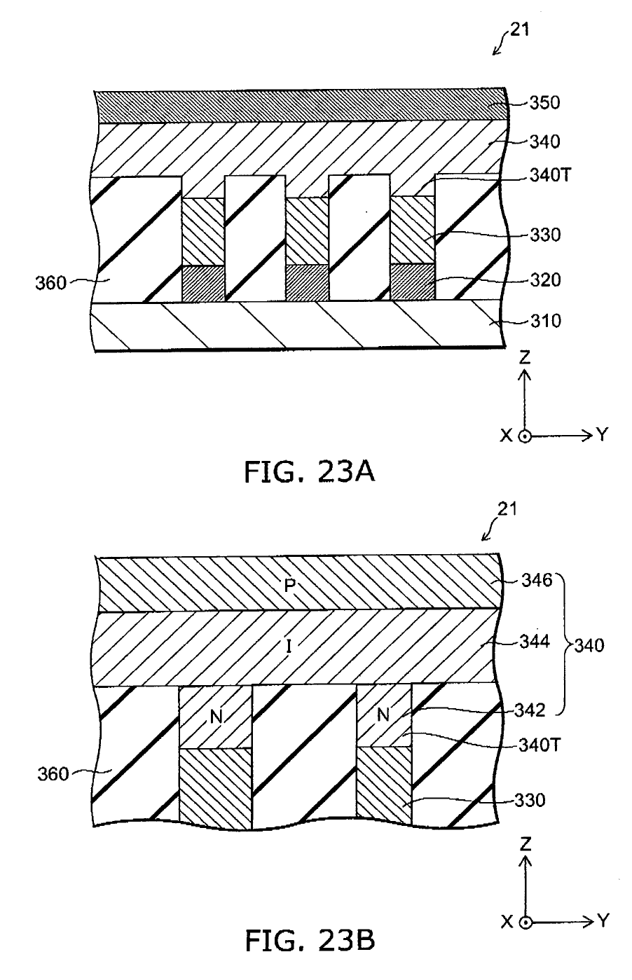

Next, another specific example (second specific example) according to this embodiment will be described with reference to FIGS. 23A to 25B.

FIG. 23A and FIG. 23B are schematic cross-sectional views illustrating configurations of another nonvolatile storage device according to the fifth embodiment of the invention.

Namely, FIG. 23A is a schematic cross-sectional view along the X-axis direction of another nonvolatile storage device 21 according to this embodiment, and FIG. 23B is a schematic cross-sectional view illustrating an enlarged portion of the rectifying element layer 340 of FIG. 23A.

This specific example is an example where a PIN (p-intrinsic-n: p-type semiconductor/intrinsic semiconductor/n-type semiconductor) diode is used as the rectifying element layer 340. In other words, the rectifying element layer 340 is a stacked structure including an n-type semiconductor layer 342, an intrinsic semiconductor layer 3441 and a p-type semiconductor layer 346.

In the other nonvolatile storage device 21 according to this embodiment illustrated in FIGS. 23A and 23B, the rectifying element layer 340 is etched to a prescribed depth in the X-axis direction. Specifically, the rectifying element layer 340 is etched to the IN junction surface (the junction surface between the intrinsic semiconductor layer 344 and the n-type semiconductor layer 342. In other words, the rectifying element layer 340 includes a protruding portion 340T that protrudes toward the recording unit 330 side.

In this specific example, the rectifying element layer 340 includes a first semiconductor layer (for example, the p-type semiconductor layer 346) of a first conductivity type (p-type), a second semiconductor layer (for example, the n-type semiconductor layer 342) of a second conductivity type (n-type), and a third semiconductor layer (for example, the intrinsic semiconductor layer 344) provided between the first semiconductor layer and the second semiconductor layer. The stack direction of the first, second, and third semiconductor layers is the Z-axis direction (a direction perpendicular to a plane that includes the first direction and the second direction).

The protruding portion 340T is the second semiconductor layer (n-type semiconductor layer 342) that protrudes beyond the third semiconductor layer (intrinsic semiconductor layer 344) on the recording layer 330 side in the Z-axis direction.

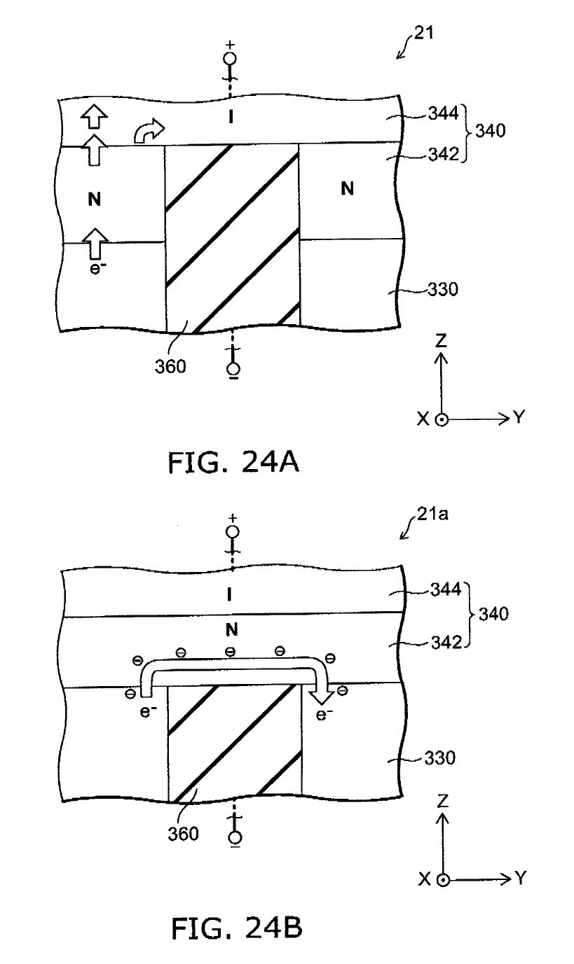

FIGS. 24A and 24B are schematic cross-sectional views illustrating the operation of the nonvolatile storage device according to the fifth embodiment of the invention.

Namely, FIG. 24A is a schematic cross-sectional view of the nonvolatile storage device 21 cut along a Y-Z plane. FIG. 24B is a schematic cross-sectional view of another nonvolatile storage device 21b according to this embodiment cut along the Y-Z plane.

In the nonvolatile storage device 21b illustrated in FIG. 24B, the n-type semiconductor layer 342 and the intrinsic semiconductor layer 344 in the rectifying element layer 340 are not etched. On the other hand, in the nonvolatile storage device 21 illustrated in FIG. 24A, the rectifying element layer 340 is etched to the IN junction interface (the junction interface between the intrinsic semiconductor layer 344 and the n-type semiconductor layer 342).

The n-type semiconductor layer 342 of the rectifying element layer 340 (PIN diode) contains many electrons as charge carriers. Therefore, in the nonvolatile storage device 21b as illustrated in FIG. 24B, there is a risk that electrons may flow through the n-type semiconductor layer 342 of the rectifying element layer 340 into the recording unit 330 of an adjacent cell when, for example, a voltage is applied to make the first wiring 320 side act as a cathode. That is, there is a risk of a leak current to the adjacent cell.

Conversely, in the nonvolatile storage device 21 illustrated in FIG. 24A, the n-type semiconductor layer 342 is etched and the inter-element insulating layer 360 is filled to provide insulation from the n-type semiconductor layer 342 of the adjacent cell. The risk that electrons may move to the adjacent cell is therefore reduced. Thus, leak current to adjacent cells is inhibited, and thereby the power consumption can be reduced further.

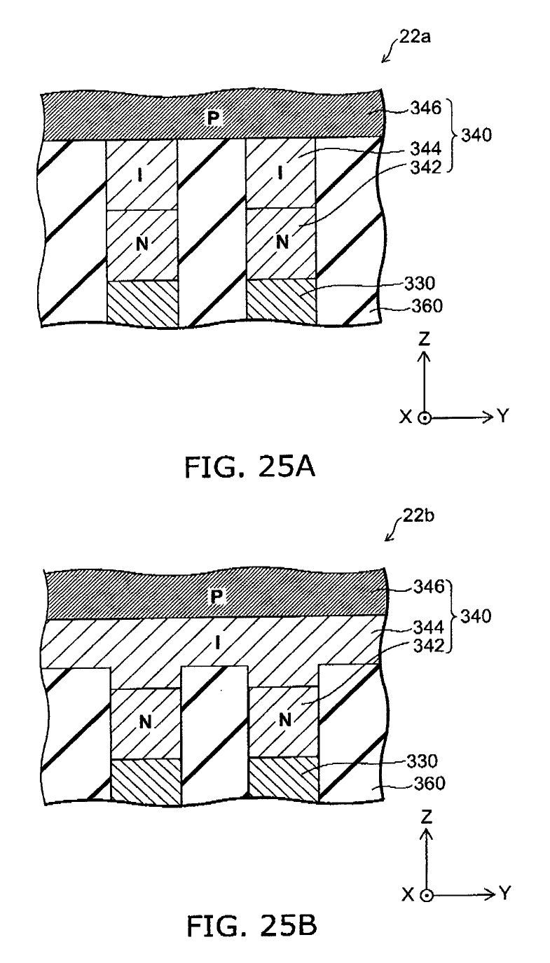

FIGS. 25A and 25B are schematic cross-sectional views illustrating configurations of other nonvolatile storage devices according to the fifth embodiment of the invention.

Namely, FIG. 25A is a schematic cross-sectional view of another nonvolatile storage device 22a according to this embodiment cut along the Y-Z plane; and FIG. 25B is a schematic cross-sectional view of another nonvolatile storage device 22b according to this embodiment cut along the Y-Z plane.

In the nonvolatile storage device 22a illustrated in FIG. 25A, the rectifying element layer 340 is etched to a PI junction interface (junction interface between the p-type semiconductor layer 346 and the intrinsic semiconductor layer 344) thereof. Thus, the protruding portion 340T may be formed by the n-type semiconductor layer 342 and the intrinsic semiconductor layer 344.

In other words, the protruding portion 340T of this specific example is the third semiconductor layer (the intrinsic semiconductor layer 344) and the second semiconductor layer (n-type semiconductor layer 342) that protrude from the first semiconductor layer (p-type semiconductor layer 346) on the recording layer 330 side in the Z-axis direction.

Leak current to adjacent cells is thereby suppressed further.

The etching depth is not particularly limited, and does not need to extend to the junction surfaces of the PIN diode as long as the n-type semiconductor layer 342 is etched.

For examples etching is performed partway through the intrinsic semiconductor layer 344 in the nonvolatile storage device 22b illustrated in FIG. 25B. Thus, the protruding portion 340T may be formed by the n-type semiconductor layer 342 and a portion of the intrinsic semiconductor layer 344.

In other words, the protruding portion 340T in this specific example is provided on a portion of the third semiconductor layer (intrinsic semiconductor layer 344) and includes a portion that protrudes on the recording layer 330 side in the Z-axis direction and the second semiconductor layer (n-type semiconductor layer 342).

Leak current to adjacent cells is thereby inhibited further.

Furthermore, etching may be performed partway through the p-type semiconductor layer 346. In such a case, the protruding portion 340T is formed by the n-type semiconductor layer 342, the intrinsic semiconductor layer 344, and a portion of the p-type semiconductor layer 346. In this case as well, leak current to adjacent cells is suppressed further.

As described above, the rectifying element layer 340 may extend along a major surface on the recording unit 330 side of the first wiring 320.

The various effects described above are provided by each of the nonvolatile storage devices 21, 21a, 21b, 22a, and 22b, namely, that (1) fabrication is easy, (2) favorable operating characteristics are obtained, and (3) the power consumption is reduced.

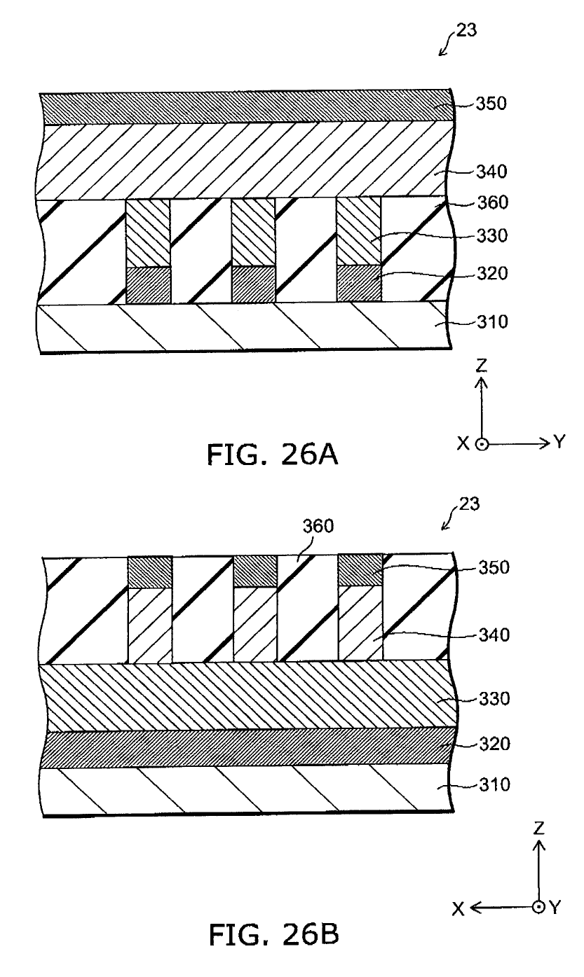

FIGS. 26A and 26B are schematic cross-sectional views illustrating the configuration of another nonvolatile storage device according to the fifth embodiment of the invention.

Namely, FIG. 26A is a schematic cross-sectional view of another nonvolatile storage device 23 according to this embodiment cut along the Y-Z plane; and FIG. 26B is a schematic cross-sectional view of the nonvolatile storage device 23 cut along the X-Z plane.

Although the other nonvolatile storage device 23 according to this embodiment has a structure similar to that of the nonvolatile storage device 21 as illustrated in FIGS. 26A and 26B, the recording unit 330 extends along the X-axis direction.

In other words, the nonvolatile storage device 23 of this specific example includes: a substrate 310; a first wiring 320 (bit line BL) aligned in a first direction (X-axis direction) provided on a major surface of the substrate 310; a second wiring 350 (word line WL) aligned in a second direction (Y-axis direction) non-parallel to the first direction; a recording unit 330 aligned along a major surface on the second wiring 350 side of the first wiring 320; and a rectifying element layer 340 aligned along a major surface on the recording unit 330 side of the second wiring 350.

The recording unit 330 is a layer that can reversibly transit between a first state and a second state having a resistance different than that of the first state due to a current supplied via the first wiring 320 and the second wiring 350. That is, the recording unit 330 is a layer in which a resistance changes due to at least one of an electric field applied and a current provided by the first wiring 320 and the second wiring 350.

This specific example also provides effects that (1) fabrication is easy, (2) favorable operating characteristics are obtained, and (3) the power consumption is reduced. In particular, the effect that (1) fabrication is easy is provided more effectively by this specific example because the recording unit 330 is not etched in the Y-axis direction, and the aspect ratio can be reduced further. Moreover, the effect that (3) the power consumption is reduced is provided more effectively by this specific example because the etched surface of the recording unit 330 is reduced.

Even in the case where the recording unit 330 has a continuous configuration in a prescribed direction (the X-axis direction in the drawing) as in the nonvolatile storage device 23, each cell along the X axis performs an independent operation. Details are described below.

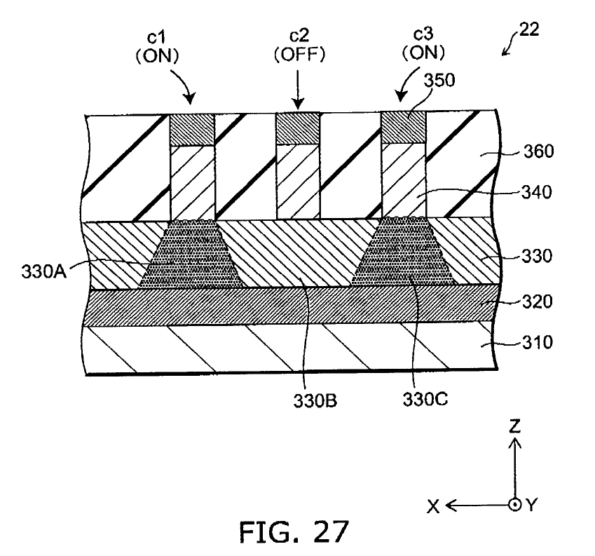

FIG. 27 is a schematic cross-sectional view illustrating the operation of the nonvolatile storage device according to the fifth embodiment of the invention.

Namely, FIG. 27 illustrates an operation of the recording unit 330 of a nonvolatile storage device 23 according to this embodiment.

As illustrated in FIG. 27, the case is assumed where cells c1 to c3 are arranged along the X axis; the cells c1 and c3 are in a selected state (ON); and the cell c2 is in an unselected state (OFF). At this time, by appropriately selecting the voltage applied between each second wiring 350 and each first wiring 320, the current that flows in each of the cells c1, c2, and c3 can be given independent values by the effects of the second wiring 350 and the rectifying element 340. Thereby, each of the cells c1 to c3 can operate independently.

For example, for the cell c1 and the cell c3 illustrated in FIG. 27, a voltage is applied between the second wiring 350 and the first wiring 320. As a result, current flows in portions of cell c1 and cell c3 of the recording units 330 (recording units 330A and 330C). The cell c1 and the cell c3 thereby transition from, for example, a high resistance state to a low resistance state and are switched to the selected (ON) state. Conversely, a voltage is not applied between the second wiring 350 and the first wiring 320 for the cell c2, and a current does not flow in the cell of the recording unit 330 (recording unit 330B). The cell c2 thereby remains in, for example, the high resistance state, and remains in an unselected (OFF) state.

As described above, the rectifying element layer 340 may extend along a major surface of the recording unit 330 side of the first wiring 320.

### THIRD EXAMPLE

The nonvolatile storage device 21b of a third example according to the fifth embodiment of the invention will now be described.

The nonvolatile storage device 21b according to this example includes the structure of the nonvolatile storage device 21 illustrated in FIG. 23. A resistance change material is used for the recording layer 336. The rectifying element layer 340 extends along a major surface on the recording unit 330 side of the word line. The rectifying element layer 340 includes the configuration described for FIG. 23B (the configuration in which a phosphorus-doped polycrystalline silicon film 342 that forms the n-type semiconductor layer of the PIN diode forms the protruding portion 340T). Also, the recording unit 330 is located at each cell.

A method for manufacturing the nonvolatile storage device will now be described.

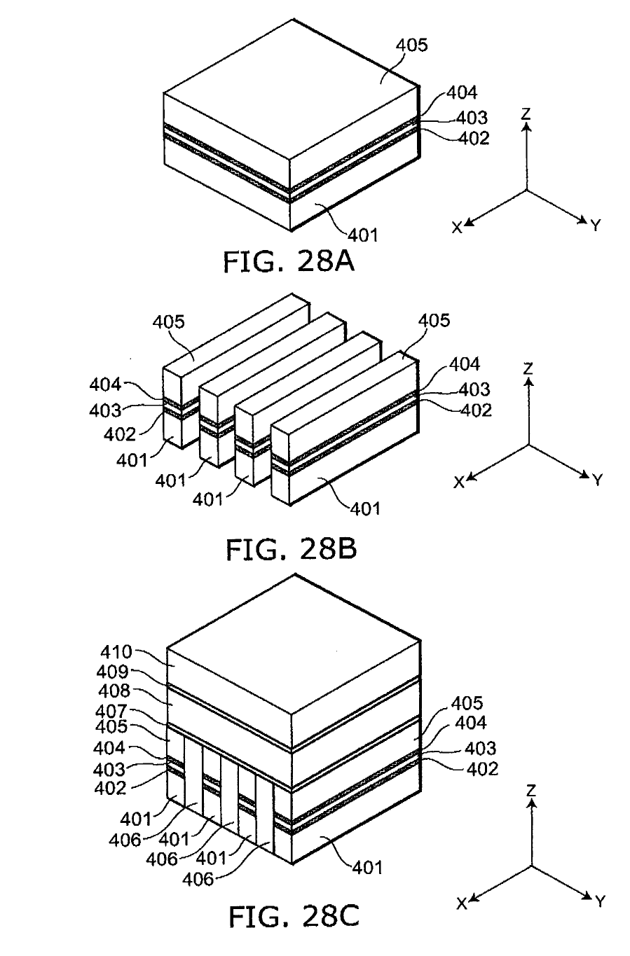

FIGS. 28A to 28C are schematic perspective views in order of the steps, illustrating the method for manufacturing the nonvolatile storage device according to the third example

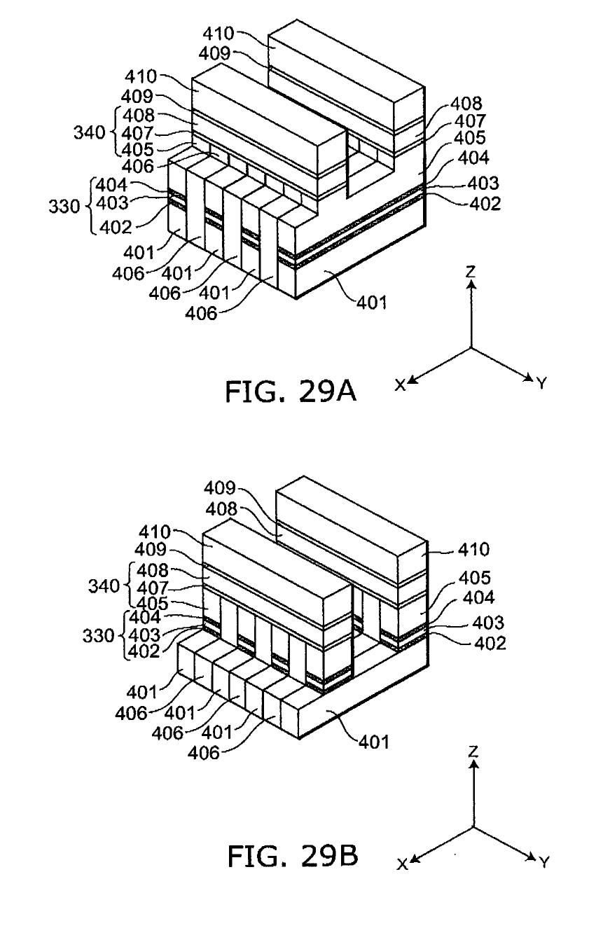

FIGS. 29A and 29B are drawings continuing from FIGS. 28A to 28C.

First, as illustrated in FIG. 28A, a tungsten film 401 that forms bit lines is formed with a thickness of 50 nm above (on a major surface of) a substrate (not illustrated) formed by, for example, a semiconductor. The tungsten film 401 need not be a bit line on the lowermost layer of a so-called multilayered memory, and may be a bit line of the second layer, third layer, and so on.

Then, a tungsten nitride film 402 that forms an electrode layer of the recording units is formed with a thickness of 10 nm on the upper surface of the configuration (major surface of the configuration). Thereupon, stack of a Ti-doped NiOₓ film 403 that forms a variable resistance layer (recording layer) is formed with a thickness of 10 nm; and a tungsten nitride film 404 that forms an electrode layer of the recording unit 330 is formed with a thickness of 10 nm.

In the case where CMP (Chemical Mechanical Polishing) is performed, a phosphorus-doped polycrystalline silicon film (a layer that forms a portion of the rectifying element layer) 405 is formed thereupon with a thickness of 50 nm to form a CMP stopper layer that functions as a stopper during planarization. The phosphorus-doped polycrystalline silicon film 405 also performs the function of a layer (the n-type semiconductor layer) of a portion of the rectifying element layer (PIN diode) formed by stacking multiple layers.

Then, as illustrated in FIG. 28B, the stacked films described above (the phosphorus-doped polycrystalline silicon film 405 to the tungsten film 401) are collectively processed into a band configuration aligned in the first direction (X-axis direction) by known lithography and reactive ion etching technology. The etching is performed to the depth of the interface between the substrate and the tungsten film 401.

Continuing as illustrated in FIG. 28C, an inter-layer dielectric film 406 is filled into openings between the stacked films processed by the etching, and the upper surface of the configuration is planarized by CMP. The phosphorus-doped polycrystalline silicon film 405 that forms the CMP stopper is thereby exposed to the surface. Then, a non-doped polycrystalline silicon film 407 that forms an intrinsic semiconductor layer and a boron-doped polycrystalline silicon film 408 that forms a p-type semiconductor layer are formed with thicknesses of 10 nm and 30 nm, respectively, on the upper surface of the configuration. These correspond to layers that form another portion of the rectifying element layer. Subsequently, stack of a tungsten nitride film 409 that forms a barrier layer is formed with a thickness of 10 nm and a tungsten film 410 that forms word lines is formed with a thickness of 50 nm on the upper surface of the configuration.

As illustrated in FIG. 29A, the stacked films described above (the phosphorus-doped polycrystalline silicon film 405 to the tungsten film 410) are collectively processed into a band configuration aligned in the second direction (Y-axis direction) non-parallel to the first direction (X-axis direction) by known lithography and reactive ion etching technology. Here, the etching is stopped at a depth partway through the phosphorus-doped polycrystalline silicon film 405.

Then, an oxidation processing is performed on the configuration, for example, in an oven in a hydrogen/oxygen mixed gas atmosphere at 800° C. or more. Side faces of the phosphorus-doped polycrystalline silicon film 405, the non-doped polycrystalline silicon film 407, and the boron-doped polycrystalline silicon film 408 that form the PIN diode are thereby selectively oxidized to form a silicon thermal oxidation film on the surface.

Here, an oxidation processing may be performed on the surface of the rectifying element layer (PIN diode) to improve the interface characteristics. However, this processing is not favorable in some cases where the tungsten film 401 that forms bit lines, the tungsten nitride film 402 that forms electrodes, tungsten nitride film 404 that forms electrodes, the tungsten nitride film 409 that forms a barrier layer, and the tungsten film 410 that forms word lines oxidize and result in a change In the conductivity, resistance change characteristics, etc. In this example, the side faces are prevented from being exposed by filling the inter-layer dielectric film 406 into the openings defined by the side faces of the stacked films described above prior to the oxidation processing. Tungsten or tungsten compounds, which are relatively resilient to oxidation, are used for the barrier layers and the wirings. Such measures enable the oxidation of only the PIN diode configuration material (selective oxidation).

Continuing as illustrated in FIG. 29B, the remaining portions of the phosphorus-doped polycrystalline silicon film 405, the tungsten nitride film 404, the Ti-doped NiOₓ film 403, and the tungsten nitride film 402 are patterned and processed into a band configuration aligned in the Y-axis direction by reactive ion etching, thereby forming columnar configurations.

By the steps described above, each resistance change recording layer is disposed between a word line and a bit line at the crosspoint where the word line and the bit line intersect; and a cell is formed in which the n-type semiconductor layer formed by the phosphorus-doped polycrystalline silicon film 405 includes the protruding portion 340T.

Then, an inter-layer dielectric film, not illustrated, is filled into the openings between the stacked films processed by etching. The nonvolatile storage device 21b (not illustrated) of the third example is thereby constructed. By repeating the configurations described above, a multilayered memory can be constructed.

Although the n-type semiconductor layer formed by the phosphorus-doped polycrystalline silicon film 405 forms the protruding portion 340T in the description above, a configuration may be used in which, for example, an intrinsic semiconductor layer is formed by the non-doped polycrystalline silicon film 407 in the steps described above in regard to FIG. 28A, after which similar steps may be performed to form the protruding portion 340T by the n-type semiconductor layer and the intrinsic semiconductor layer.

Conversely, an n-type semiconductor layer may not be formed by the phosphorus-doped polycrystalline silicon film 405 in the steps described above in regard to FIG. 28A, and for example, the layers up to the tungsten nitride film 404 may be formed, after which similar steps may be performed to form a configuration without a protruding portion 340T.

Although a Ti-doped NiOₓ film was used for the resistance change material (recording layer) of this example, the resistance change material may include any substance in which a resistance state changes due to a voltage applied to both ends. The resistance change material (recording layer) may include, for example, at least one selected from the group consisting of C, NiOₓ, Cr-doped SrTiO₃₋ₓ, PrₓCa_{y}MnO_{z}, Ti-doped NiOₓ, ZrOₓ, NiOₓ, ZnOₓ, TiOₓ, TiOₓN_{y}, CuOₓ, GdOₓ, CuTeₓ, HfOₓ, ZnMnₓO_{y}, and ZnFeₓO_{y}.

Although tungsten nitride is used for the electrode of the recording unit in this example, the electrode may include any material that does not react with the resistance change material and compromise the variable resistance properties. Specifically, in addition to tungsten nitride, for example, titanium nitride, titanium aluminum nitride, tantalum nitride, titanium silicide nitride, tantalum carbide, titanium silicide, tungsten silicide, cobalt silicide, nickel silicide, nickel platinum silicide, platinum, ruthenium, platinum-rhodium, iridium, and the like may be used.

The diode material that forms the rectifying element layer 340 may include a combination of a semiconductor such as silicon, germanium, and the like and/or a metal oxide semiconductor such as NiO, TiO, CuO, InZnO, and the like.

Various modifications are also possible for the materials used for the word lines, the bit lines, the barrier layer, and the CMP stopper layer.

Moreover, the film thickness of each film described above is but one example, and various modifications are possible.

### FOURTH COMPARATIVE EXAMPLE

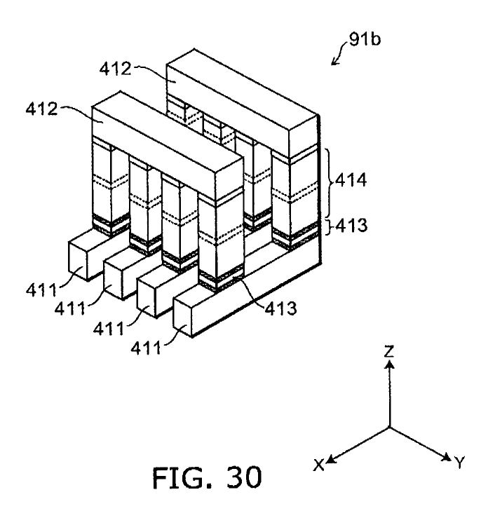

FIG. 30 is a schematic perspective view illustrating the configuration of a nonvolatile storage device of a fourth comparative example.

Illustrations of inter-layer insulating films are omitted in FIG. 30 for better understanding of the structure. In a nonvolatile storage device 91b of the fourth comparative example illustrated in FIG. 30, for example, a PIN diode 414 is disposed between a bit line 411 and a word line 412, and locates in each cell similarly to a resistance change element (recording unit) 413.

Operating characteristics and leak current of the nonvolatile storage device 21b according to the third example and the nonvolatile storage device 91b of the fourth comparative example will now be described.

TABLE 3 illustrates the erasing voltage and the leak current density of the diode junction for the nonvolatile storage device 21b according to the third example and the nonvolatile storage device 91b of the fourth comparative example. The erasing voltage is the voltage when the erasing current (reset current) is 200 μA.

TABLE 3

| | | FOURTH |
|---|---|---|
| | THIRD EXAMPLE | COMPARATIVE |
| | NONVOLATILE | EXAMPLE |
| | STORAGE | NONVOLATILE |
| | DEVICE 21b | STORAGE DEVICE 91b |
| ERASING VOLTAGE | 1.9 V | 2.8 V |
| JUNCTION LEAK | 7.6 × 10⁻⁸ A/cm² | 1.2 × 10⁻⁷ A/cm² |
| CURRENT DENSITY | | |

It can be seen in TABLE 3 that the erasing voltage of the nonvolatile storage device 21b according to the third example is lower than that of the nonvolatile storage device 91b of the fourth comparative example. It is considered that the applied voltage is efficiently applied to the Ti-doped NiOₓ film 403 that forms the resistance change layer by the extension of the diode. It can be seen also that the junction leak current density of the nonvolatile storage device 21b is lower than that of the nonvolatile storage device 91b. In other words, the etched surface area is relatively small, and therefore it is considered that the occurrence of leak current is inhibited.

### FOURTH EXAMPLE

A nonvolatile storage device of a fourth example according to the fifth embodiment of the invention will now be described.

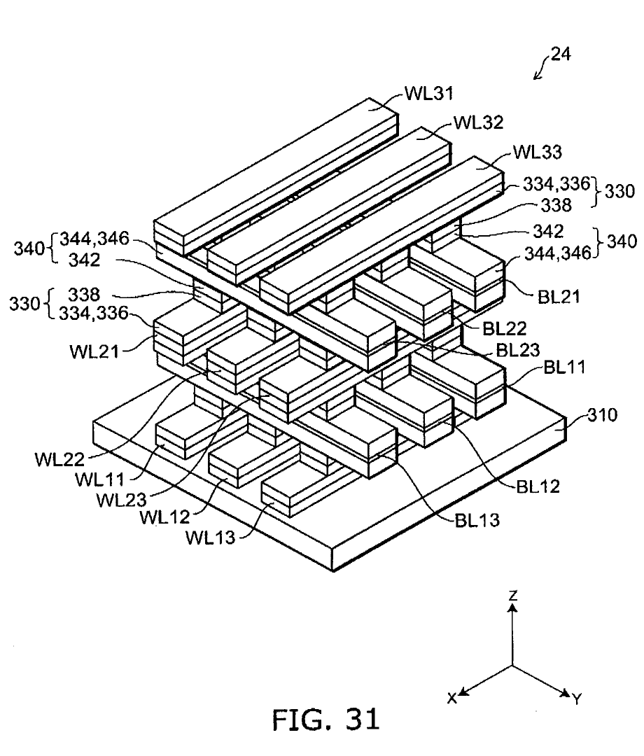

FIG. 31 is a schematic perspective view illustrating the configuration of the nonvolatile storage device of the fourth example according to the fifth embodiment of the invention.

A nonvolatile storage device 24 of the fourth example according to this embodiment illustrated in FIG. 31 is a multi-layered nonvolatile storage device using multiple stack of the nonvolatile storage device 21 illustrated in FIGS. 23A and 23B. That is, four layers of the recording units 330 are stacked in this specific example. Each word line and bit line is shared between adjacent cells above and below in a shared bit line/word line structure. The stacked structure in each cell is vertically inverted between cells that are adjacent above and below. Namely, the arrangement of the recording unit 330 (electrode layer 334/recording layer 336/electrode layer 338) and the rectifying element layer 340 (n-type semiconductor layer 342/intrinsic semiconductor layer 344/p-type semiconductor layer 346) is vertically symmetric. A phase change material is used for the recording layer 336.

The rectifying element layer 340 extends along a major surface on the recording unit 330 side of the bit line. The rectifying element layer 340 has the configuration described above in regard to FIG. 23B (a configuration in which the n-type semiconductor layer 342 of the PIN diode is the protruding portion 340T). The recording unit 330 has the configuration illustrated in FIG. 26 in which the word line extends along the major surface on the bit line side.

A method for manufacturing the nonvolatile storage device 24 will now be described.

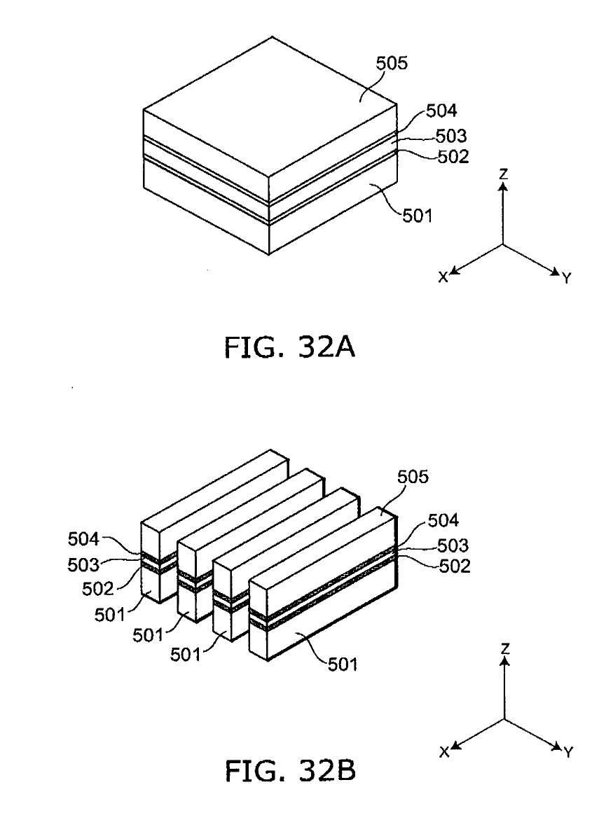

FIGS. 32A and 32B are schematic perspective views in order of the steps, illustrating the method for manufacturing the nonvolatile storage device according to the fourth example of the invention.

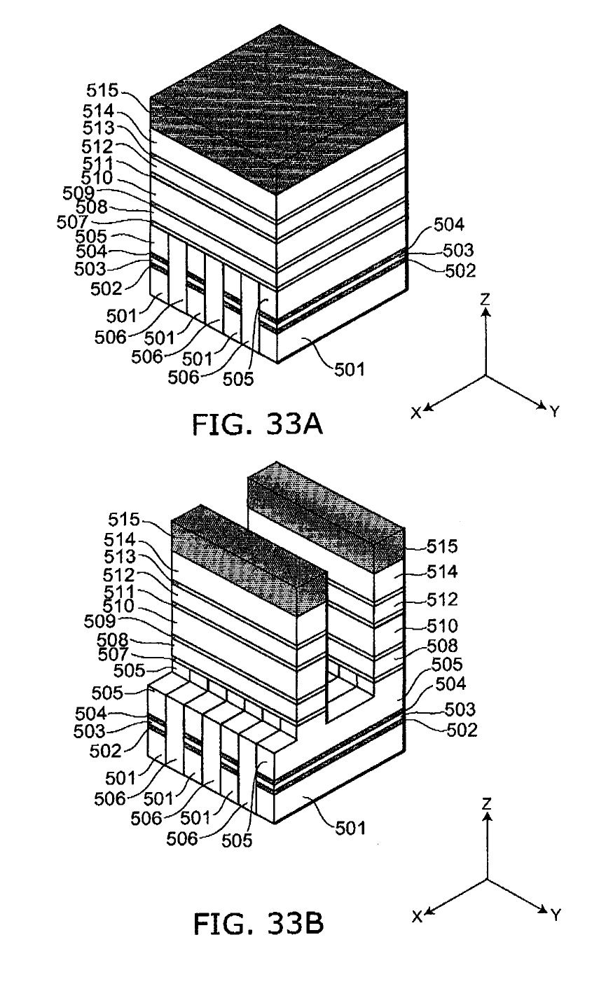

FIGS. 33A and 33B are drawings continuing from FIGS. 32A and 32B.

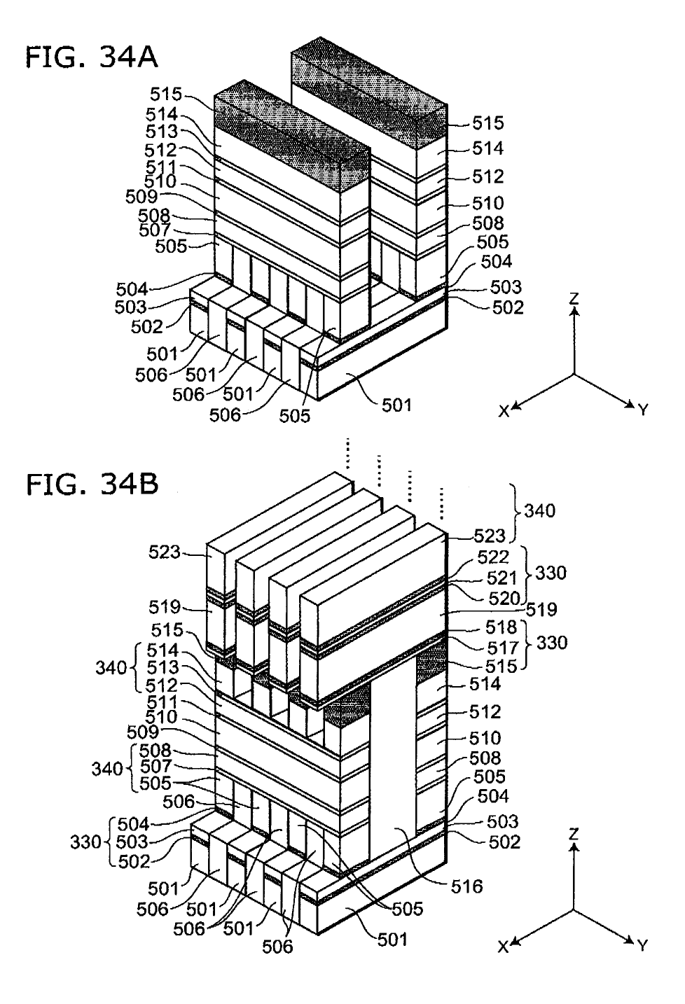

FIGS. 34A and 34B are drawings continuing from FIGS. 33A and 33B.

As illustrated in FIG. 32A, a tungsten film 501 that forms word lines is formed with a thickness of 50 nm above (on a major surface of) a substrate (not illustrated) formed by, for example, a semiconductor. Similar to the first example, the tungsten film 501 that forms word lines need not form the word lines of a lowermost layer of a so-called multilayered memory, and may form the word lines of the second layer, third layer, and so on.

Continuing, a tungsten nitride film 502 that forms an electrode layer of the recording units is formed with a thickness of 10 nm on the upper surface of the configuration (major surface of the configuration). Thereupon, stack of a Ge₂Sb₂Te₅ film 503 that forms a resistance change material (phase change layer, recording layer) is formed with a thickness of 20 nm; and a tungsten nitride film 504 that forms a reaction prevention layer between the resistance change material and the Si is formed with a thickness of 10 nm.

A phosphorus-doped polycrystalline silicon film 505 is formed with a thickness of 50 nm to form a CMP stopper layer. The phosphorus-doped polycrystalline silicon film 505 also performs the function of a layer (the n-type semiconductor layer) of a portion of the rectifying element layer (PIN diode) formed by stacking multiple layers.

Then, as illustrated in FIG. 32B, the configuration is collectively patterned into a band configuration aligned in the first direction (X-axis direction) by known lithography and reactive ion etching technology. The etching is performed to the depth of the interface between the substrate and the tungsten film 501.

Continuing as illustrated in FIG. 33A, an inter-layer dielectric film 506 is filled into openings between the stacked films processed by the etching, and the upper surface of the configuration is planarized by CMP. Then, a non-doped polycrystalline silicon film 507 that forms an intrinsic semiconductor layer and a boron-doped polycrystalline silicon film 508 that forms a p-type semiconductor layer are formed with thicknesses of 10 nm and 30 nm, respectively, on the upper surface of the configuration. Subsequently, stack of a tungsten nitride film 509 that forms a barrier layer is formed with a thickness of 10 nm on the upper surface of the configuration; and thereupon, a tungsten film 510 that forms bit lines is formed with a thickness of 50 nm; a tungsten nitride film 511 that forms a barrier layer is formed with a thickness of 10 nm; a boron-doped polycrystalline silicon film 512 that forms a p-type semiconductor layer is formed with a thickness of 30 nm; a non-doped polycrystalline silicon film 513 that forms an intrinsic semiconductor layer is formed with a thickness of 10 nm; a phosphorus-doped polycrystalline silicon film 514 that forms an n-type semiconductor layer is formed with a thickness of 50 nm; and a tungsten nitride film 515 that forms a CMP stopper layer is formed with a thickness of 50 nm.

Then, as illustrated in FIG. 33B, the stacked films described above (the tungsten nitride film 515 to the phosphorus-doped polycrystalline silicon film 505) are collectively processed into a band configuration aligned in the second direction (Y-axis direction) by known lithography and reactive ion etching technology. Here, the etching is performed to the upper portion of the phosphorus-doped polycrystalline silicon film 505.

Subsequently, an oxidation processing is performed on the configuration, for example, by an RTP (Rapid Thermal Process) in a hydrogen/oxygen mixed gas atmosphere at 950° C. or more. Side faces of the phosphorus-doped polycrystalline silicon film 505 that forms the n-type semiconductor layer, the non-doped polycrystalline silicon film 507 that forms the intrinsic semiconductor layer, the boron-doped polycrystalline silicon film 508 that forms the p-type semiconductor layer, the boron-doped polycrystalline silicon film 512 that forms the p-type semiconductor layer, the non-doped polycrystalline silicon film 513 that forms the intrinsic semiconductor layer, and the phosphorus-doped polycrystalline silicon film 514 that forms the n-type semiconductor layer, which form PIN diodes, are thereby selectively oxidized to form a silicon thermal oxidation film on the surface.

Here, an oxidation processing may be performed on the surface of the rectifying element layer (PIN diode) to improve the interface characteristics as described above. However, this processing is not favorable in some cases where other components oxidize and result in the conductivity flucturation, resistance change characteristics, etc. This example prevents the side faces of these films from such exposure by filling the inter-layer dielectric film 506 into the openings defined by the side faces of the tungsten film 501 that forms word lines, the tungsten nitride film 502 that forms electrodes, the Ge₂Sb₂Te₅ film 503 that is a resistance change material, and the tungsten nitride film 504 that forms a reaction prevention layer prior to the oxidation processing. Tungsten or tungsten compounds, which are relatively resilient to oxidation, are used for the barrier layers and the wiring electrode layers. Such measures enable the oxidation of only the PIN diode configuration material (selective oxidation).

Continuing as illustrated in FIG. 34A, the remaining portions of the phosphorus-doped polycrystalline silicon film 505 and the tungsten nitride film 504 are collectively processed into a band configuration aligned in the Y-axis direction by reactive ion etching.

Then, as illustrated in FIG. 34B, an inter-layer dielectric film 516 is filled into openings between the stacked films patterned by the etching, and the upper surface is planarized by, for example, CMP. A Ge₂Sb₂Te₅ film that is a resistance change material is formed with a thickness of 20 nm on the upper surface of the configuration; and thereupon, stack of a tungsten nitride film 518 that forms an electrode layer is formed with a thickness of 10 nm; a tungsten film 519 that forms word lines is formed with a thickness of 50 nm; a tungsten nitride film 520 that forms an electrode layer of the recording units is formed with a thickness of 10 nm; a Ge₂Sb₂Te₅ film 521 that is a resistance change material is formed with a thickness of 20 nm; a tungsten nitride film 522 that forms an electrode layer of recording units is formed with a thickness of 10 nm; and a phosphorus-doped polycrystalline silicon film 523 that forms a CMP stopper layer is formed with a thickness of 50 nm. The phosphorus-doped polycrystalline silicon film 523 also performs the function of a layer (the n-type semiconductor layer) of a portion of the rectifying element layer (PIN diode) formed by stacking multiple layers.

Continuing, the stacked configuration described above (the phosphorus-doped polycrystalline silicon film 523 to the phosphorus-doped polycrystalline silicon film 514) is collectively processed into a band configuration aligned in the first direction (X-axis direction) by known lithography and reactive ion etching technology. The etching is performed to a depth of the interface between the non-doped polycrystalline silicon film 513 and the phosphorus-doped polycrystalline silicon film 514.

Thus, a memory cell of a stacked resistance change memory is formed.

Then, by repeating steps similar to those described above, a multiple layer memory cell can be constructed. A description thereof is omitted.

Thus, the nonvolatile storage device 24 is constructed. The nonvolatile storage device 24 is a multilayered nonvolatile storage device in which phase change recording units 330 are multiply stacked. The rectifying element layer 340 includes the configuration described above in regard to FIG. 23B (the configuration in which the n-type semiconductor layer 342 of the PIN diode is the protruding portion 340T). The recording unit 330 includes the configuration illustrated in FIG. 26 (the configuration extending along the major surface on the bit line side of the word line).

Although the n-type semiconductor layer described above is the protruding portion 340T, a configuration in which the n-type semiconductor layer and the intrinsic semiconductor layer form the protruding portion 340T and a configuration in which the protruding portion 340T does not exist can be made by actions such as appropriately changing the timing at which layers of the n-type semiconductor layer and the intrinsic semiconductor layer are formed, and changing the etching depth.

For example, to form a configuration in which the n-type semiconductor layer and the intrinsic semiconductor layer form the protruding portion 340T, a layer of the non-doped polycrystalline silicon film 507 of the step described above in regard to FIG. 32A may be formed; similar steps may be subsequently performed; and then the non-doped polycrystalline silicon film 513 also may be etched by an etching step of a band configuration aligned in the X-axis direction as described above in regard to FIG. 34B.

To make a configuration in which the protruding portion 340T does not exist, the phosphorus-doped polycrystalline silicon film 505 is not formed by the step described above in regard to FIG. 32A; films up to the tungsten nitride film 504 are formed; similar steps are subsequently performed; and then etching is performed up to the tungsten nitride film 515 by an etching step of a band configuration aligned in the X-axis direction as described above in regard to FIG. 34B.

Although a Ge₂Sb₂Te₅ (GST) film is used as the resistance change element (recording layer) of this example, the resistance change material may-include any substance in which a resistance state thereof changes due to a joule heat occurring due to a voltage applied to both ends. For example, the resistance change material (recording layer) may include at least one selected from the group consisting of Ge₂Sb₂Te₅, N-doped Ge₂Sb₂Te₅, and O-doped Ge₂Sb₂Te₅ in which a dopant is added to a chalcogenide GST, GeₓSb_{y}, InₓGe_{y}Te_{z}, and the like.

Although a heater is not used in this example, a heater material for facilitating a resistance change may be used, including tantalum oxide, niobium oxide, titania, and the like.

Although tungsten nitride was used for the electrode of the recording unit of this example, any material that does not react with the resistance change material and compromise the variable resistance properties in the electrode layer may be used. Specifically, for example, titanium nitride, titanium aluminum nitride, tantalum nitride, titanium silicide nitride, tantalum carbide, titanium silicide, tungsten silicide, cobalt silicide, nickel silicide, nickel platinum silicide, platinum, ruthenium, platinum-rhodium, iridium, and the like may be used.

The diode material may include a semiconductor such as silicon, germanium, and the like; and may include a metal oxide semiconductor such as NiO, TiO, CuO, InZnO, and the like.

Various modifications are also possible for the materials used for the word lines, the bit lines, the barrier layers, and the CMP stopper layer.

Moreover, the film thickness of each film described above is but one example, and various modifications are possible.

### FIFTH ELEMENT

A nonvolatile storage device of a fifth example according to the fifth embodiment of the invention will now be described.

A nonvolatile storage device 25 according to the fifth example (not illustrated) includes the configuration of the nonvolatile storage device 21 illustrated in FIG. 23. The rectifying element layer 340 extends along a major surface on the recording unit 330 side of the second wiring 350. The rectifying element layer 340 includes the configuration described above in regard to FIG. 25B, namely, the configuration in which the n-type semiconductor layer 342 and a portion of the intrinsic semiconductor layer 344 form the protruding portion 340T. The recording unit 330 is provided at a point for each cell.

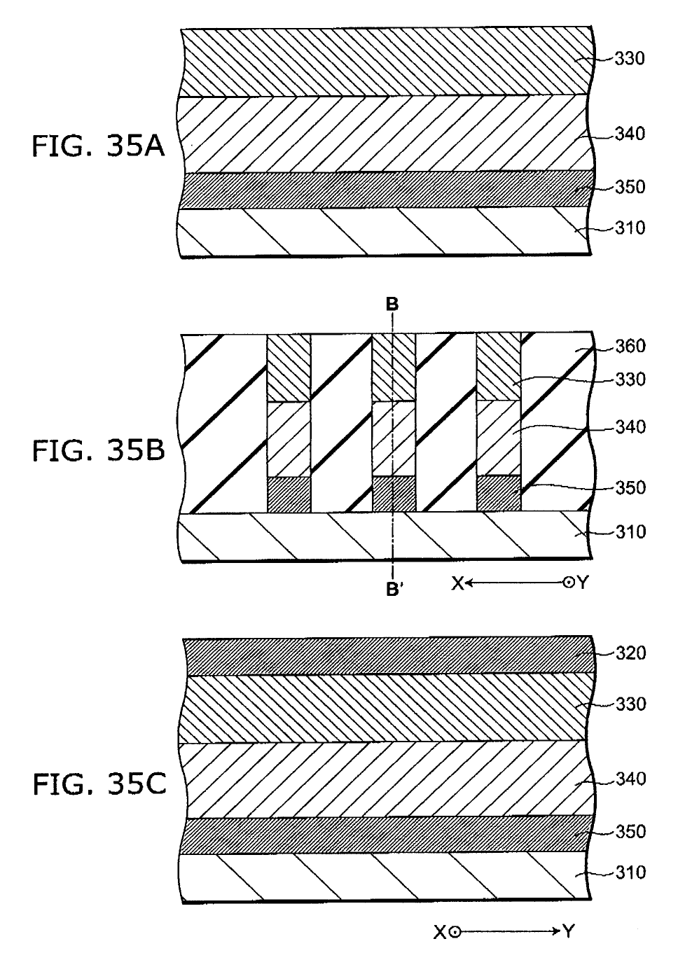

FIGS. 35A to 35C are schematic cross-sectional views in order of the steps, illustrating a method for manufacturing the nonvolatile storage device according to the fifth example of the invention.

FIG. 35C is a cross-sectional view along line B-B′ of FIG. 35B.

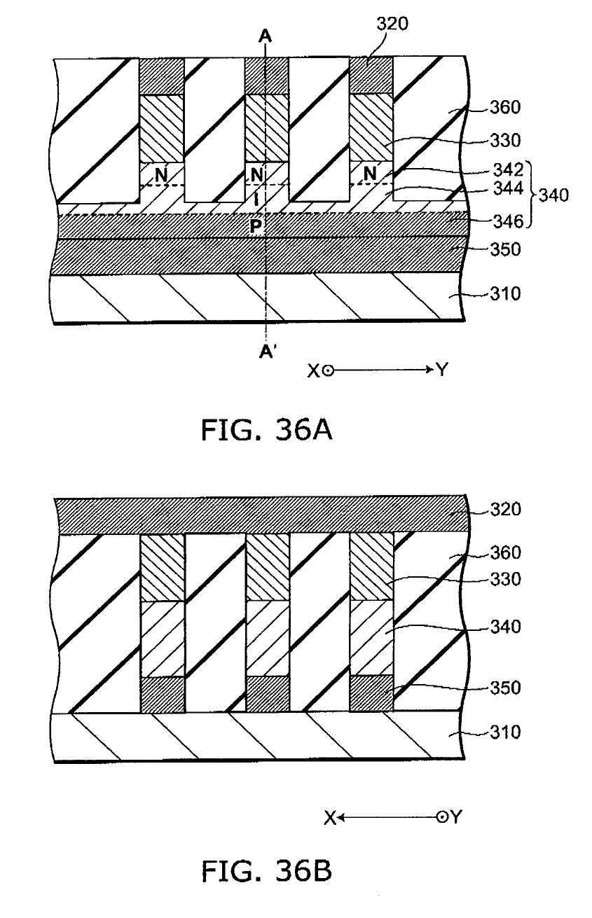

FIGS. 36A and 36B are drawings continuing from FIGS. 35A to 35C.

FIG. 36B is a cross-sectional view along line A-A′ of FIG. 36A.

First, as illustrated in FIG. 35A, the second wiring 350, the rectifying element layer 340, and the recording unit 330 are formed, sequentially from the bottom, above (on a major surface of) the substrate 310.

Then, as illustrated in FIG. 35B, etching is performed on the configuration in the Y-axis direction. The etching is performed to the depth of the interface between the substrate 310 and the second wiring 350. An inter-layer dielectric film (inter-element insulating layer 360) is then filled into openings made by etching, and the surface of the configuration (major surface of the configuration) is planarized by, for example, CMP.

Continuing as illustrated in FIG. 35C, the first wiring 320 is formed on the major surface (upper surface) of the configuration.

As illustrated in FIGS. 36A and 36B, etching is performed on the configuration in the X-axis direction. The etching is performed only to the upper portion of the intrinsic semiconductor layer 344. An inter-layer dielectric film (inter-element insulating layer 360) is then filled into openings made-by etching.

By the steps described above, the nonvolatile storage device 25 in which the rectifying element layer 340 includes the configuration described above in regard to FIG. 25B is constructed.

The material of each component may include those described above in the third example and the fourth example.

An oxidation processing may be performed for the rectifying element layer 340 as necessary after etching in the Y-axis direction and the X-axis direction. In such a case, favorable characteristics such as operations of the elements, etc., may be provided by using a material resilient to oxidation as the second wiring 350, the recording unit 330, and the first wiring 320.

As described above, this embodiment provides a nonvolatile storage device and a method for manufacturing the same having favorable operating characteristics and easy fabrication.

Hereinabove, embodiments of the invention are described with reference to specific examples. However, the invention is not limited to these specific examples. For example, one skilled in the art may appropriately select specific configurations of components of the nonvolatile storage device and the method for manufacturing the same from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all nonvolatile storage devices and methods for manufacturing the same that can be obtained by an appropriate design modification by one skilled in the art based on the nonvolatile storage devices and the methods for manufacturing the same described above as embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

1. A nonvolatile storage device comprising:
a plurality of component memory layers,
the plurality of component memory layers being stacked in a direction perpendicular to a layer surface,
each of the plurality of component memory layers including:
a first wiring;
a second wiring provided non-parallel to the first wiring; and
a stacked structure unit provided between the first wiring and the second wiring, the stacked structure unit including a recording layer having a resistance changing property due to at least one of an applied electric field and a current provided by the first wiring and the second wiring,
at least one of the first wiring and the second wiring having a protruding portion provided on a portion opposed to the recording layer and protruding toward the recording layer side.

2. The device according to claim 1, wherein the recording layer includes at least one selected from the group consisting of C, NbOₓ, Cr-doped SrTiO₃₋ₓ, PrₓCa_{y}MnO_{z}, Ti-doped NiOₓ, ZrOₓ, NiOₓ, ZnOₓ, TiOₓ, TiOₓN_{y}, CuOₓ, GdOₓ, CuTeₓ, HfOₓ, ZnMnₓO_{y}, ZnFeₓO_{y}, GeₓSb_{y}Te_{z}, N-doped GeₓSb_{y}Te_{z}, O-doped GeₓSb_{y}Te_{z}, GeₓSb_{y}, and InₓGe_{y}Te_{z}.

3. The device according to claim 1, wherein the stacked structure unit includes at least one of a first barrier metal provided on the first wiring side of the stacked structure unit, and a second barrier metal provided on the second wiring side of the stacked structure unit, and a resistivity of the protruding portion is lower than a resistivity of the at least one of the first and second barrier metals.

4. The device according to claim 3, wherein at least one of the first barrier metal and the second barrier metal includes at least one selected from the group consisting of titanium nitride, tungsten nitride, titanium aluminum nitride, tantalum nitride, titanium silicide nitride, tantalum carbide, titanium silicide, tungsten silicide, cobalt silicide, nickel silicide, nickel platinum silicide, platinum, ruthenium, platinum-rhodium, and iridium.

5. The device according to claim 1, wherein the stacked structure unit further includes a rectifying element provided between a recording layer and at least one of the first wiring and the second wiring, and the rectifying element includes at least one selected from the group consisting of silicon, germanium, NiO, TiO, CuO, and InZnO.

6. The device according to claim 1, wherein one of the first wiring and the second wiring of one of the plurality of component memory layers is shared as one of the first wiring and the second wiring of another component memory layer adjacent to the one of the plurality of component memory layers in a direction perpendicular to the layer surface.

7. A nonvolatile storage device comprising:
a first wiring aligned in a first direction;
a second wiring aligned in a second direction non-parallel to the first direction;
a recording layer disposed between the first wiring and the second wiring, the recording layer having a resistance changing property due to at least one of an applied electric field and a current provided by the first wiring and the second wiring; and
a rectifying element layer provided between the first wiring and the recording layer, at least a portion of the rectifying element layer aligned in the first direction.

8. The nonvolatile storage device according to claim 7, wherein the rectifying element layer includes a protruding portion protruding toward the recording layer side.

9. The device according to claim 8, wherein
the rectifying element layer includes a first semiconductor layer of a first conductivity type, a second semiconductor layer of a second conductivity type, and a third semiconductor layer provided between the first semiconductor layer and the second semiconductor layer, a stack direction of the first, second, and third semiconductor layers being perpendicular to a plane including the first direction and the second direction, and
the protruding portion is the second semiconductor layer protruding from the third semiconductor layer toward the recording layer side in a direction perpendicular to the plane including the first direction and the second direction.

10. The device according to claim 8, wherein
the rectifying element layer includes a first semiconductor layer of a first conductivity type, a second semiconductor layer of a second conductivity type, and a third semiconductor layer provided between the first semiconductor layer and the second semiconductor layer, a stack direction of the first, second, and third semiconductor layers being perpendicular to a plane including the first direction and the second direction, and
the protruding portion is the third semiconductor layer and the second semiconductor layer protruding from the first semiconductor layer toward the recording layer side in a direction perpendicular to the plane including the first direction and the second direction.

11. The device according to claim 8, wherein
the rectifying element layer includes a first semiconductor layer of a first conductivity type, a second semiconductor layer of a second conductivity type, and a third semiconductor layer provided between the first semiconductor layer and the second semiconductor layer, a stack direction of the first, second and third semiconductor layers being perpendicular to a plane including the first direction and the second direction, and
the protruding portion includes a portion provided on a portion of the third semiconductor layer and protruding toward the recording layer side in a direction perpendicular to the plane including the first direction and the second direction, and the second semiconductor layer.

12. The device according to claim 8, wherein the recording layer includes at least one selected from the group consisting of Ti-doped NiOₓ, C, NbOₓ, Cr-doped SrTiO₃₋ₓ, PrₓCa_{y}MnO₂, Ti-doped NiOₓ, ZrOₓ, NiOₓ, ZnOₓ, TiOₓ, TiOₓN_{y}, CuOₓ, GdOₓ, CuTeₓ, HfOₓ, ZnMnₓO_{y}, ZnFeₓO_{y}, Ge₂Sb₂Te₅, N-doped Ge₂Sb₂Te₅, Ge₂Sb₂Te₅, GeₓSb_{y}, and InₓGe_{y}Te_{z}.

13. The device according to claim 8, wherein the rectifying element layer includes at least one selected from the group consisting of silicon, germanium, NiO, TiO, CuO, and InZnO.

14. The device according to claim 8, wherein at least one of the first and the second wiring includes at least one selected from the group consisting of tungsten, tungsten nitride, and tungsten carbide.

15. A method for manufacturing a nonvolatile storage device, the nonvolatile storage device including component memory layers multiply stacked on one another, the component memory layer including a first wiring aligned in a first direction, a second wiring aligned in a second direction non-parallel to the first direction, and a stacked structure unit provided between the first wiring and the second wiring, the stacked structure unit including a recording layer and a rectifying element layer, the method comprising;
a first step stacking, on a substrate, a stacked film serving as the stacked structure unit and at least one of a first conductive film serving as the first wiring and a second conductive film serving as the second wiring in a stack direction perpendicular to the first direction and the second direction, and processing the stacked film an d on e of the first conductive film and the second conductive film into a band configuration aligned in the first direction;
a second step filling an inter-layer dielectric film between the stacked film and at least one of the first conductive film and the second conductive film processed into the band configuration; and
a third step collectively processing the stacked film, the inter-layer dielectric film, and another of the first conductive film and the second conductive film into a band configuration aligned in the second direction,
at least one of the first step, the second step and the third step performing at least forming a protruding portion being formed on at least one of the first wiring and the second wiring, and a portion of the stacked film, the protruding portion protruding in the stack direction, and forming at least a portion of the stacked film aligned in one of the first direction and the second direction,

16. The method for manufacturing the device according to claim 15, further comprising:
a fourth step, provided between the second step and the third step, forming the third conductive film above the first conductive film, a stacked film serving as the stacked structure unit, and a second conductive film serving as a portion of the second wiring being filled by the inter-layer dielectric film and above the inter-layer dielectric film,
the first step stacking the first conductive film, the stacked film, and the second conductive film on the substrate in the stack direction, and processing the first conductive film, the stacked film, and the second conductive film into a band configuration aligned in the first direction,
the second step filling the inter-layer dielectric film between the first conductive film, the stacked film, and the second conductive film being patterned into the band configuration, and
the third step collectively processing the stacked film, the second conductive film, the inter-layer dielectric film, and the third conductive film into a band configuration aligned in the second direction.

17. The method for manufacturing the device according to claim 15, further comprising:
a fifth step, provided between the second step and the third step, forming a second conductive film serving as the second wiring on the stacked film and the inter-layer dielectric film,
the first step stacking the first conductive film, the stacked film, and a sacrificial layer on the substrate in the stack direction, and processing the first conductive film, the stacked film, and the sacrificial layer into a band configuration aligned in the first direction,
the second step filling the inter-layer dielectric film between the first conductive film and the stacked film being processed into the band configuration, and
the third step collectively processing the second conductive film, the inter-layer dielectric film, and the stacked film into a band configuration aligned in the second direction, and forming the protruding portion by processing a portion of the first conductive film on the stacked film side and causing the portion of the first conductive film to protrude in a direction from the first conductive film toward the stacked film parallel to the stack direction.

18. The method for manufacturing the device according to claim 15, further comprising,
a sixth step, provided between the second step and the third step, removing a sacrificial layer and making a trench-shaped opening; and
a seventh step, provided between the sixth step and the third step, forming a second conductive film serving as the second wiring, the second conductive film configured to cover above the first conductive film and the stacked film filled by the inter-layer insulating film and above the inter-layer dielectric film and to fill the trench-shaped opening,
the first step stacking the first conductive film, the stacked film, and the sacrificial layer on the substrate in the stack direction, and patterning the first conductive film, the stacked film, and the sacrificial layer into a band configuration aligned in the first direction,
the second step filling the inter-layer dielectric film between the first conductive film, the stacked film, and the sacrificial layer being patterned into the band configuration, and
the third step collectively processing the stacked film, the inter-layer insulating film, and the second conductive film into a band configuration aligned in the second direction, and forming the protruding portion by causing a portion of the second conductive film to protrude in a direction from the second conductive film toward the stacked film parallel to the stack direction.

19. The method for manufacturing the device according to claim 15, wherein the first step includes
stacking, on the substrate in the stack direction, the first conductive film, a stacked film serving as the stacked structure unit, and a second conductive film serving as a portion of the second wiring, and processing the first conductive film, the stacked film, and the second conductive film into a band configuration aligned in the first direction, and
performing partial etching of the stacked film to collectively process a first wiring aligned in the first direction and a portion of a rectifying element layer of the stacked film into a band configuration, and forming the protruding portion by causing a portion of the rectifying element layer to protrude in a direction from the stacked film toward the first conductive film parallel to the stack direction.

20. The method for manufacturing the device according to claim 15, further comprising:
an eighth step, provided between the second step and the third step, forming, above a layer serving as one portion of a rectifying element layer in the stacked structure unit, a layer serving as another portion of the rectifying element layer; and
a ninth step, provided between the eighth step and the third step, forming, above the layer serving as the other portion of the rectifying element layer, a layer serving as the second wiring,
the first step stacking the first conductive film, the stacked film, and the second conductive film on the substrate in the stack direction, and processing the first conductive film, the stacked film, and the second conductive film into a band configuration aligned in the first direction,
the first step including:
a tenth step forming, above a layer serving as the recording layer as a portion of the stacked film, the layer serving as the one portion of the rectifying element layer; and
an eleventh step processing the layer serving as the one portion of the rectifying element layer, the layer serving as the recording layer, and the layer forming the second wiring into a band configuration by etching,
the second step filling an inter-element insulating layer between the layer serving as the one portion of the rectifying element layer, the layer serving as the recording layer, and the layer serving as the second wiring being processed into the band configuration, and
the third step forming the protruding portion by causing the rectifying element layer to protrude in a direction from the second conductive film toward the stacked film parallel to the stack direction by performing etching on the layer serving as the second wiring, the layer serving as the other portion of the rectifying element layer, and the stacked film including the layer serving as the one portion of the rectifying element layer.
